(19) United States
(12) Patent Application Publication
(10) Pub. No.: US 2006/0079027 A1
(43) Pub. Date: Apr. 13, 2006

(54) Semiconductor device and its manufacturing method

(75) Inventors: Kohei Yamada, Kofu (JP); Yasuharu Ichinose, Ryuo (JP); Hiroyuki Nagase, Ryuo (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Renesas Technology Corporation, Tokyo (JP)

(21) Appl. No.: 10/514,471

(22) PCT Filed: May 16, 2003
(86) PCT No.: PCT/JP03/06113

§ 371 Date: Aug. 9, 2005

(30) Foreign Application Priority Data
May 16, 2002 (JP) 2002-142024

(51) Int. Cl. H01L 21/48; H01L 21/44; H01L 21/50

(52) U.S. Cl. 438/121

(57) ABSTRACT

A manufacturing method of a thin and small-sized semiconductor device, which is integrated into an electronic instrument. A silicon wafer is prepared, and oxide films are formed on the main face and the rear face of the wafer. An insulating film is selectively formed on the main face of the wafer to make through holes. Metal-laminated films are formed on the oxide films on the bottoms of the through holes, and further first and second metal films are formed on the metal-laminated films to form metal pedestals. Next, a semiconductor chip wherein a diode is formed is fixed onto the main face of one of the metal pedestals through one electrode of the chips, and the other electrode is connected to the other of the metal pedestals through an electroconductive wire. Next, the semiconductor chip, the wire and so on are covered with an insulating resin layer, and then the silicon wafer and the oxide film are removed so that the oxide film stuck onto the rear face of the sealant remains. The oxide film on the rear face of the resin layer is etched and removed, and a metal plating film is formed on the surfaces of the metal pedestals exposed to the rear face of the resin layer. The resin layer is then cut lengthwise and breadthwise to manufacture semiconductor devices.

### TECHNICAL FIELD

The present invention relates to a resin-sealed semiconductor device, and a manufacturing method thereof, in particular, a technique useful for being applied to a manufacturing technique of a thin semiconductor device having a surface mount structure.

### BACKGROUND ART

Electronic equipment is required to have elements mounted at a higher density from the viewpoint of the function thereof and to be made lighter, smaller and thinner from the viewpoint of packaging. Therefore, many electronic members integrated into electronic equipment have been shifted into structure capable of being surface-mounted. In order to decrease manufacturing costs of electronic members, as the package form thereof, resin package (resin-sealing), which is low in the cost of the material thereof and is good in the productivity thereof, is used in many cases.

For example, a surface mount type resin-sealed semiconductor device is disclosed in Japanese laid open Patent No. Hei 7 (1995)-147359. This document describes a semiconductor device wherein transistor chips or diode chips are sealed in a resin (sealant), and drawings therein illustrate a structure wherein gull-wing leads are projected from both sides of the resin (sealant) and a structure wherein flat leads are projected from both sides of the bottom face of the sealant.

No semiconductor device using, as a supporting substrate thereof, a glass-epoxy substrate, a ceramic substrate, or a metal substrate (lead frame) can be made thin since the support substrate is integrated into the semiconductor device. Therefore, Japanese laid open Patent No. 2001-223320 discloses a technique for manufacturing a circuit device which comprises using an electroconductive foil in order to make the device thin, making separating grooves in one surface of this electroconductive foil to form electroconductive paths having a die pad, a bonding pad and distribution lines, fixing and bonding plural circuit elements on the die pad, connecting electrodes of the circuit elements to the lines through wires, forming an insulating resin on the surface of the electroconductive foil by transfer molding so as to cover the circuit elements, the lines, and the wires with the resin, removing the rear face of the electroconductive foil by a given thickness to make the respective electroconductive paths independently of each other, subjecting the rear face of the electroconductive paths to treatment (plating-treatment), and cutting the insulating resin.

Japanese laid open Patent No. Hei 10 (1998)-50748 discloses a technique of forming a plating layer (a layer which is made of nickel, copper or the like and has a thickness of about 10 to 200 mm) selectively onto a single surface of a support (a metal plate made of stainless steel material) to form an electronic-circuit-element-mounting section and a wiring section, mounting electronic circuit elements thereon, and next peeling the electronic-circuit-element-mounting section and the wiring section from the support to yield an electronic member device, or performing sealing of the electronic circuit elements (resin-sealing by bonding: the whole or a part of the sections is covered with a resin film instead of resin-sealing) and subsequently peeling the electronic-circuit-element-mounting section and the wiring section which are firmly integrated with resin from the support to yield an electronic member device; and others.

As one of surface mount type resin-sealed semiconductor devices, a two-terminal diode is known. A conventional diode is illustrated in FIGS. 35 and 36.

A semiconductor device 90 in FIG. 35 has a structure wherein leads 92 are projected into a gull-wing form from the central, middle stages at both sides of a sealant 91 made of insulating resin. This is a structure wherein a semiconductor element (semiconductor chip) 93 having an electrode on each of the front and rear faces is fixed through the rear face electrode onto the lower face of the inner end of one of the leads 92 and further the front face electrode of the semiconductor chip 93 and the other of the leads 92 are connected to each other through a wire 94. About the size of the sealant 91 in this structure, the length thereof is 1.7 mm, the width is 1.3 mm, and the height is 0.9 mm. The semiconductor chip 93 is, for example, a structure wherein a p conductivity type semiconductor region is formed on the surface layer portion (main face) of an n type conductivity type silicon substrate, an electrode (cathode electrode) is formed on the rear face of the silicon substrate, and an electrode (anode electrode) connected to the p conductivity type semiconductor region is formed on the main face.

A semiconductor device 90 in FIG. 36 has a structure wherein flat leads 92 are straightly projected from the centers near the bottom face at both sides of a sealant 91 made of insulating resin. The pair of the leads 92 is bent and turned into one step inside the sealant 91. In the same manner as illustrated in FIG. 35, the structure thereof is a structure wherein a semiconductor element (semiconductor chip) 93 having an electrode on each of the front and rear faces is fixed through the rear face electrode onto the upper face of the inner end of one of the leads 92 and further the front face electrode of the semiconductor chip 93 and the other of the leads 92 are connected to each other through a wire 94. In this structure, the size of the sealant 91 is made into a length of 1.2 mm, a width of 0.8 mm, and a height of 0.6 mm so as to be smaller and thinner than the semiconductor device in FIG. 35.

The present Applicant has also been developing diodes (semiconductor devices) which are smaller and thinner. In the case that the conventional structure of this kind is used to produce a diode, it has been found out that there are problems as described below.

(1) A semiconductor device is manufactured by use of a lead frame made of metal. The lead frame has a thickness of about 0.1 mm, and a semiconductor chip has a thickness of about 0.15 mm. A wire also has a given height since the wire is connected into a loop form so as to be bonded. Furthermore, it is necessary to form a sealant which covers the inner end portion of the lead, the semiconductor chip and the wire. It is therefore difficult to set the height of the sealant into 0.5 mm or less.

(2) In the manufacture of a resin-sealed semiconductor device, a lead frame subjected to cutting and bending works with a high precision is used so that costs for the works increase, and further a sealant is formed by transfer molding, which yields a large amount of useless material. Accordingly, the manufacture costs of the semiconductor device tend to become expensive.

(3) In the case that a lead frame is used to form a sealant by transfer molding, thereby manufacturing a semiconductor device, it is necessary to perform work for removing a leaked portion of resin (resin burry or flash) generated in the transfer molding and further it is necessary to use a minute and high-precision mold for each package in working steps such as the step of bending and cutting leads. Thus, costs of instruments including the mold increase to hinder the manufacture costs of the semiconductor device from being reduced.

Each of these problems is encountered not only in the manufacture of diodes but also in all resin-sealed semiconductor devices having the above-mentioned structure, wherein semiconductor chips which will constitute transistors or IC (integrated circular devices) are integrated.

In the meantime, as described above, there is a method of using an electroconductive foil or a metal plate as a supporting member and finally removing the supporting member, by a given thickness, from the rear face side thereof or peeling the supporting member, thereby manufacturing a circular device or an electronic member device. According to this, the device can be made still thinner.

In the manufacture of a semiconductor device, a semiconductor substrate called wafer is used. The wafer process, wherein this wafer is used, is an established technique high in productivity.

Thus, the present inventors have made investigations on manufacturing technique of a semiconductor device, wherein this wafer is used as a supporting member, and have made the present invention.

An object of the present invention is to provide a manufacturing technique of a semiconductor device wherein facilities for the wafer process using a semiconductor substrate can be used.

An object of the invention is to provide a thin semiconductor device and a manufacturing method thereof.

Another object of the invention is to provide a thin and small-sized semiconductor device, and a manufacturing method thereof.

Still another object of the invention is to provide a manufacturing method of a semiconductor device which makes it possible to reduce manufacture costs.

An additional object of the invention is to provide a semiconductor device on which plural semiconductor elements, which are active members, and passive members are mounted, and a manufacturing method thereof.

The above-mentioned objects of the present invention, other objects thereof, and new features thereof will become clear from the description in the present Description and the attached drawings.

### DISCLOSURE OF THE INVENTION

Outlines of typical embodiments of inventions disclosed in the present application are briefly described in the following:

(1) The manufacturing method of semiconductor devices of the present invention comprises the steps of:

preparing a semiconductor substrate (silicon wafer),

forming oxide films over the main face and the rear face of the semiconductor substrate,

forming a metal-laminated film which constitutes metal layers (pedestals or metal pedestals) over the oxide film,

forming a first metal film which constitutes the metal layers over the metal-laminated film,

forming a second metal film which constitutes the metal layers over the surface of the first metal layer,

fixing an electronic member having, over the main face thereof, one or more electrodes, to the main face of at least one metal layer out of the metal layer through the rear face thereof,

connecting the electrode of the electronic member to the other metal layers through an electroconductive wire or electroconductive wires,

forming, over the main face of the semiconductor substrate, a resin layer comprising an insulating resin for covering the electronic member and the wire,

removing the semiconductor substrate and the oxide film formed to the rear face of the semiconductor substrate so as to cause the oxide film over the main face of the semiconductor substrate to remain,

etching and removing the oxide film remaining to the rear face of the resin layer,

forming a metal plating layer over the surface of the metal layer exposed to the rear face of the resin layer, and

cutting the resin layer lengthwise and breadthwise to form the semiconductor devices.

The rear faces of the metal pedestals and the rear face of the sealant are positioned on substantially the same plane, and further the metal plating film is formed to the rear faces of the metal pedestals to produce a standoff structure. The metal pedestals are positioned inside the circumferential edge of the sealant. The metal pedestals each comprise a metal-laminated film, a first metal film which is a strong member over this metal-laminated film, and a second metal film formed over the surface of this first metal film. The second metal film is formed to extend from the main face of the first metal film to a portion of circumferential faces thereof to become thicker than the first metal film. A wiring region comprising one or more insulating films and one or more electroconductive layers are formed to the rear face of the sealant, and the metal pedestals are each made of a member comprising the above-mentioned plural electroconductive layers.

According to the method (1), (a) each of facilities for established wafer process technique is used to perform fabrication, and further to form the resin layer, remove the silicon wafer and the oxide film, and subsequently cut and separate the resin layer to manufacture semiconductor devices. Therefore, thin and small-sized semiconductor devices can be manufactured at low costs.

(b) Since the rear faces of the metal layers (pedestals or metal pedestals) are projected from the rear face of the sealant to produce a standoff structure, mounting failure caused by the interposition of an foreign substance is hardly caused at the time of mounting.

(c) Since each of the metal pedestals is positioned inside the circumferential edge of the sealant, a short circuit is not easily caused between the metal pedestal and an electronic member adjacent thereto in the state that the member is mounted.

(d) Since the tips of the metal pedestals become thick inside the sealant, the metal pedestals, that is, external electrode terminals do not fall easily from the sealant. Thus, the reliability becomes high.

(e) Since the wiring region is formed to the rear face of the sealant, the positions of the external electrode terminals can be selected at will. Wiring design in the wiring region becomes easy.

(f) The sizes of the metal pedestals can be changed in accordance with the use purpose thereof so that the pedestals can be made into member-mounting sections for mounting semiconductor chips and others, wire-bonding sections for connecting wires, electrode-fixing sections for fixing electrodes of chip members, and/or electrode-fixing sections for mounting electrodes of semiconductor chips in a flip chip manner. As a result, various electronic members can be mounted, and can also be made into an MCM.

### BRIEF DESCRIPTION OF THE DRAWINGS

FIG. 1 is a schematic sectional view illustrating a semiconductor device which is an embodiment (embodiment 1) of the present invention.

FIG. 2 is a see-through perspective view of the semiconductor device of the embodiment 1.

FIG. 3 is a see-through plan view of the semiconductor device of the embodiment 1.

FIG. 4 is a see-through side view of the semiconductor device of the embodiment 1.

FIGS. 5(a) to 5(f) are schematic sectional process charts illustrating a process from the step of preparing a silicon wafer to the step of forming core metal layers on the main face of the wafer in the semiconductor device manufacturing method in the embodiment 1.

FIG. 6 is a schematic plan view of the wafer illustrating the arrangement state and the shapes of the core metal layers.

FIGS. 7(a) to 7(e) are schematic sectional process charts illustrating a process from the step of forming plating films on the surfaces of the core metal layers to the step of connecting electrodes of a semiconductor element fixed on the main face of a member-mounting section to the main face of a wire-bonding section through a wire in the semiconductor device manufacturing method in the embodiment 1.

FIGS. 8(a) to 8(d) are schematic sectional process charts illustrating a process from the step of forming a resin layer on the main face of the wafer to the step of removing the wafer and a silicon oxide film on the main face of the wafer in the semiconductor device manufacturing method in the embodiment 1.

FIG. 9 is a schematic sectional view illustrating a molding die and others in a transfer molding machine for forming the resin layer.

FIG. 10 is a schematic plan view illustrating a cull, a runner, a gate and a cavity made by clamping the molding die.

FIGS. 11(a) to 11(d) are schematic sectional process charts illustrating a process from the step of forming plating films for mounting on the rear faces of the metal-laminated films which are exposed to the rear face of the resin layer to the step of cutting the resin layer lengthwise and breadthwise to be made into individual pieces, thereby manufacturing plural semiconductor devices in the semiconductor device manufacturing method in the embodiment 1.

FIGS. 12(a) and 12(b) are schematic sectional process charts illustrating another example of the step of making the resin layer into individual pieces in the semiconductor device manufacturing method in the embodiment 1.

FIG. 13 is a schematic view illustrating a mounting state of the semiconductor device of the embodiment 1.

FIG. 14 is a schematic see-through plan view illustrating a transistor manufactured by the semiconductor device manufacturing method of the embodiment 1.

FIG. 15 is a schematic see-through plan view illustrating an IC manufactured by the semiconductor device manufacturing method of the embodiment 1.

FIG. 16 is a schematic sectional view illustrating a semiconductor device which is another embodiment (embodiment 2) of the present invention.

FIG. 17 is a schematic sectional view illustrating a mounting state of the semiconductor device of the embodiment 2.

FIGS. 18(a) to 18(f) are schematic sectional process charts illustrating a process from the step of preparing a silicon wafer to the step of making hollows in the main face of the wafer in the semiconductor device manufacturing method in the embodiment 2.

FIGS. 19(a) to 19(e) are schematic sectional process charts illustrating from the step of removing a resist film on the wafer main face to the step of cutting the resin layer lengthwise and breadthwise to be made into individual pieces, thereby forming plural semiconductor devices in the semiconductor device manufacturing method in the embodiment 2.

FIG. 20 is a schematic sectional view illustrating a semiconductor device which is a still another embodiment (embodiment 3) of the present invention.

FIG. 21 is a schematic see-through plan view of the semiconductor device of the embodiment 3.

FIG. 22 is a schematic bottom view of the semiconductor device of the embodiment 3.

FIGS. 23(a) to 23(d) are schematic sectional process charts illustrating a process from the step of an oxide film on the surface of a silicon wafer to the step of forming metal-laminated films in the semiconductor device manufacturing method in the embodiment 3.

FIGS. 24(a) to 24(c) are schematic sectional process charts of a process from the step of forming a photoresist film to the step of patterning a metal layer in the semiconductor device manufacturing method in the embodiment 3.

FIGS. 25(a) to 25(d) are schematic sectional process charts of a process from the step of applying an insulating paste for bonding chips to the step of removing the wafer in the semiconductor device manufacturing method in the embodiment 3.

FIGS. 26(a) to 26(c) are schematic sectional process charts of a process from the step of the silicon oxide film on the rear face of a resin sealing layer to the step of cutting the resin sealing layer lengthwise and breadthwise to be made into individual pieces, thereby manufacturing plural semiconductor devices in the semiconductor device manufacturing method in the embodiment 3.

FIG. 27 is a schematic sectional view illustrating a semiconductor device (DBM) which is a different embodiment (embodiment 4) of the present invention.

FIG. 28 is a schematic see-through plan view wherein members mounted on the DBM of the embodiment 4 and others are see-through.

FIG. 29 is an equivalent circuit schematic of the DBM of the embodiment 4.

FIG. 30 is a schematic sectional view illustrating a semiconductor device (VCO) which is a different embodiment (embodiment 5) of the present invention.

FIG. 31 is a schematic see-through plan view wherein members mounted on the VCO of the embodiment 4 and others are see-through.

FIG. 32 is an equivalent circuit schematic of the VCO of the embodiment 5.

FIG. 33 is a schematic see-through plan view wherein members mounted on a semiconductor device (MCM) which is a different embodiment (embodiment 6) of the present invention and others are see-through.

FIG. 34 is a schematic sectional view of a portion of the MCM of the embodiment 6.

FIG. 35 is a see-through front view of a conventional semiconductor device, for surface mount, which has gull-wing leads.

FIG. 36 is a see-through front view of a conventional semiconductor device, for surface mount, which has flat leads.

### BEST MODES FOR CARRYING OUT THE INVENTION

Embodiments of the present invention are described in detail hereinafter with reference to the drawings. In all the figures for explaining the embodiments of the invention, the same reference numbers are attached to members having the same function, and repeated description thereof is omitted.

### Embodiment 1

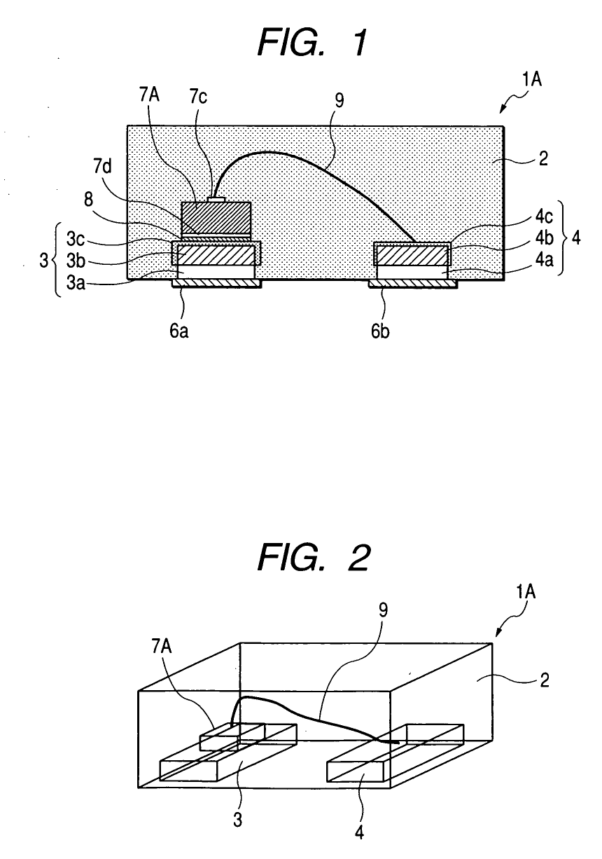

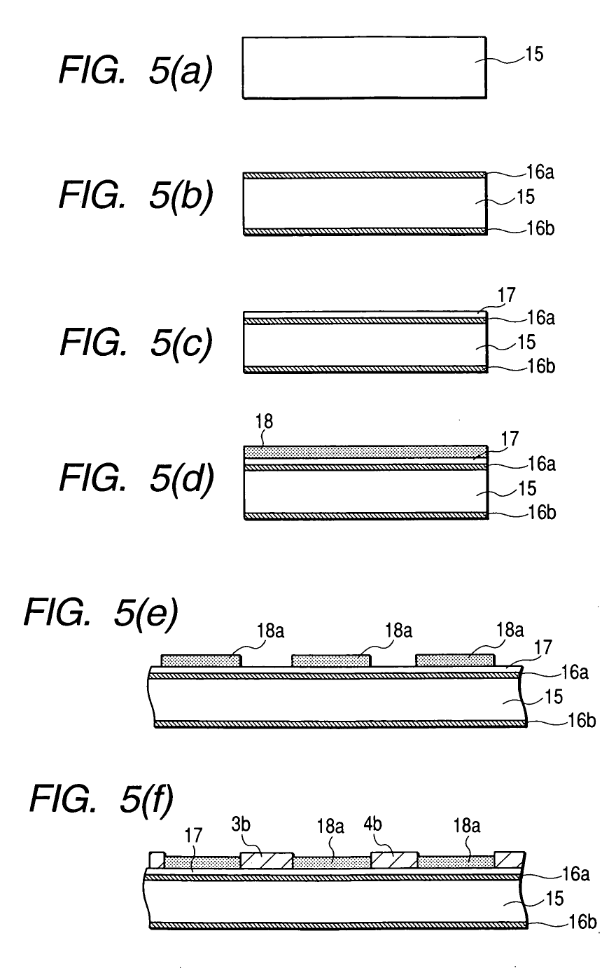

FIGS. 1 to 15 are views concerned with a semiconductor device which is an embodiment (embodiment 1) of the present invention, and a manufacturing method thereof, in which FIGS. 1 to 4 are views concerned with the semiconductor device, and FIGS. 5 to 11 are views concerned with the manufacturing method of the semiconductor device.

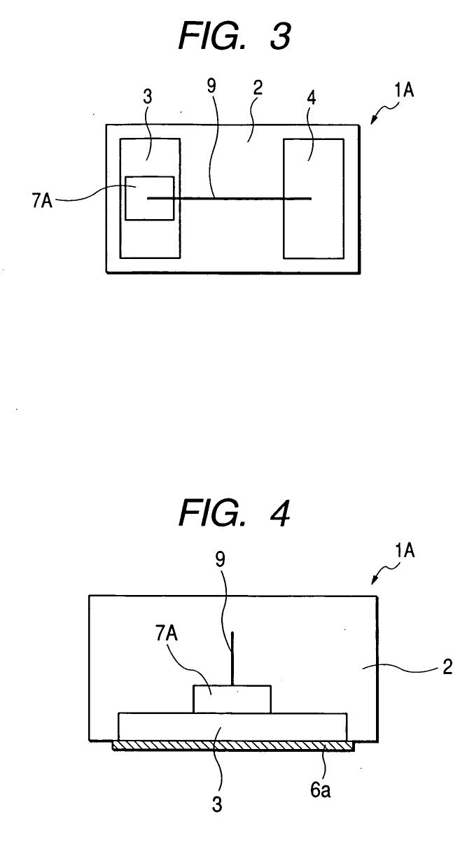

In the present embodiment 1, an example wherein the present invention is applied to a manufacturing technique of a diode as the semiconductor device is described. The semiconductor device 1A (diode 1A) has a structure as illustrated in FIGS. 1 to 4. FIG. 1 is a schematic sectional view illustrating the diode 1A, FIG. 2 is a see-through perspective view of the diode 1A, FIG. 3 is a see-through plan view of the diode 1A, and FIG. 4 is a see-through side view of the diode 1A.

As illustrated in FIGS. 1 and 2, plural metal layers (pedestals or metal pedestals) made of a metal are arranged on the rear face (bottom face) of a rectangular sealant (package) 2 made of an insulating resin. In the present embodiment 1, the metal pedestals are a member-mounting section 3 and a wire-bonding section 4. About both of the member-mounting section 3 and the wire-bonding section 4, their circumferential faces and main faces are covered with the sealant 2, and their rear faces are exposed from the sealant 2. The exposed faces and the rear face of the sealant 2 are positioned on substantially the same plane. Plating films, that is, plating films 6a and 6b for mounting are formed on the rear faces of the member-mounting section 3 and the wire-bonding section 4 (see FIG. 4). The mounting plating films 6a and 6b constitute external electrode terminals.

The metal layers (pedestals or metal pedestals) are classified into the member-mounting section and the wire-bonding section in the present embodiment 1, and a different example thereof may be an electrode fixing section. The electrode-fixing section is classified into an electrode-fixing section for fixing electrodes of a chip member wherein the electrodes are positioned at both ends, such as a chip condenser or a chip resistance; or an electrode-fixing section in the case that electrodes formed on a single face of a semiconductor element (semiconductor chip) are connected to each other in a flip chip manner. An example wherein an electrode-fixing section is used will be described later in a different embodiment.

A semiconductor element (semiconductor chip) 7A made of silicon, wherein a diode is formed, is fixed onto the main face of the member-mounting section 3. This semiconductor element 7A is the diode, and has a structure having an electrode (for example, a cathode electrode) 7d suitable for wire bonding on the rear face of the chip, and having an electrode (for example, an anode electrode) 7c on the main face thereof. The electrode 7d on the rear face is mechanically and electrically connected through an electroconductive adhesive 8 to the member-mounting section 3. The electrodes 7c and 7d are Au electrodes.

The electrode 7c on the main face of the semiconductor chip 7A and the main face of the wire-bonding section 4 are electrically connected to each other through an electroconductive wire 9 (see FIGS. 1 to 4). As the wire 9, for example, a gold wire of 20 μm diameter is used.

The member-mounting section 3 and the wire-bonding section 4 are composed of subjacent metal-laminated film 3a and 4a, core metal layers 3b and 4b formed thereon, and plating films 3b and 4b covering the core metal layers 3b and 4b, respectively. The metal-laminated films 3a and 4a are base members for forming the core metal layers 3b and 4b and the plating films 3c and 4c, respectively, and further function as underlying electrodes for forming external electrode terminals. The core metal layers 3b and 4b are strong members and are formed into a relatively large thickness. The plating films 3c and 4c are plating films formed in order to make good the fixation of electronic members, electrodes of chip members, and electrodes of semiconductor chips and the connection of wires, thereby obtaining good joint or connection. For example, in the surface thereof, Au is used.

The core metal layers 3b and 4b are each made of, for example, a Ni layer of 35 μm thickness. The metal-laminated layers 3a and 4a are each made of, for example, a Ti layer (lower layer) of 0.3 μm thickness and a Ni layer of 0.2 μm thickness. The plating films 3c and 4c are each made of, for example, a Ni layer (lower layer) of 10 μm thickness and a Au layer of 0.5 μm thickness. The metal-laminated film may each be a combination of a Ti layer (lower layer) with a Au layer.

Since the plating layers 3c and 4c are formed to cover the main face and the circumferential faces of the metal-laminated films 3b and 4b, respectively, as illustrated in FIG. 1, the core metal layers 3b and 4b become thicker than the metal-laminated films 3a and 4a, respectively. Thus, the member-mounting section 3 and the wire-bonding section 4 become structures wherein the sections are not easily fallen out from the sealant 2 (anchor effect).

The mounting plating films 6a and 6b are made of such a metal that when the diode 1A is mounted on a mounting substrate such as a wiring substrate, the member-mounting section 3 and the wire-bonding section 4 are easily connected to lands which are to be connected to wiring formed on the main face of the mounting substrate. The mounting plating films 6a and 6b are formed by an electroless plating method. For example, the mounting plating films 6a and 6b are each composed of a Ni layer (lower layer) of 10 μm thickness and a Au layer of 0.5 μm thickness. The thickness of the whole becomes 10.5 μm.

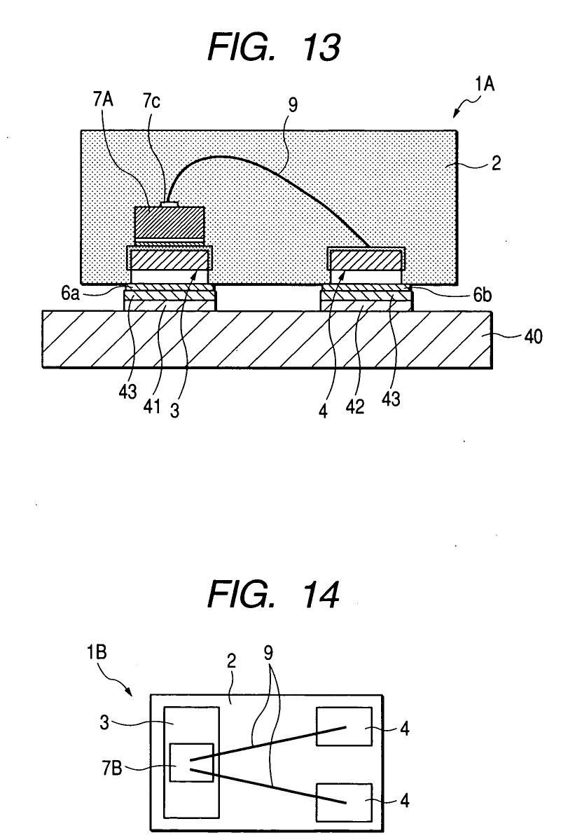

FIG. 13 is a schematic sectional view illustrating a mounting state of the semiconductor device 1A. Lands 41 and 42 corresponding to the member-mounting section 3 and the wire-bonding section 4 of the semiconductor device 1A are formed on the main face of a mounting substrate 40 made of a wiring substrate. The member-mounting section 3 and the wire-bonding section 4 are positioned and fixed onto the lands 41 and 42 through an adhesive 43 such as solder. In the mounting of this semiconductor device 1A, the rear faces of the member-mounting section 3 and the wire-bonding section 4 have the so-called standoff structure wherein their rear faces are projected out, by about the thickness of the mounting plating films 6a and 6b, from the rear face of the sealant 2. Therefore, even if an foreign substance comes in between the main face of the mounting substrate 40 and the rear face of the sealant 2, the member-mounting section 3 and the wire-bonding section 4 are surely connected to the lands 41 and 42 as far as the foreign substance is not very large. An example wherein this standoff is made larger will be described later as embodiment 2.

About the size of the semiconductor device 1A, the length is about 1.0 mm, the width is about 0.5 mm and the height is about 0.35 mm, and the device 1A is thin and small-sized.

Since the core metal layers 3b and 4b are made of magnetic material, the semiconductor device 1A can be held by a magnet. Therefore, in the processing of classifying characteristics of the semiconductor device 1A, the processing of stamping characters or symbols on the surface of the sealant 2 of the semiconductor device 1A, or a taping package processing of packaging the semiconductor device 1A into a tape, transportation or delivery works can be attained by use of magnetism. As a result, manufacture costs of the semiconductor device 1A can be decreased.

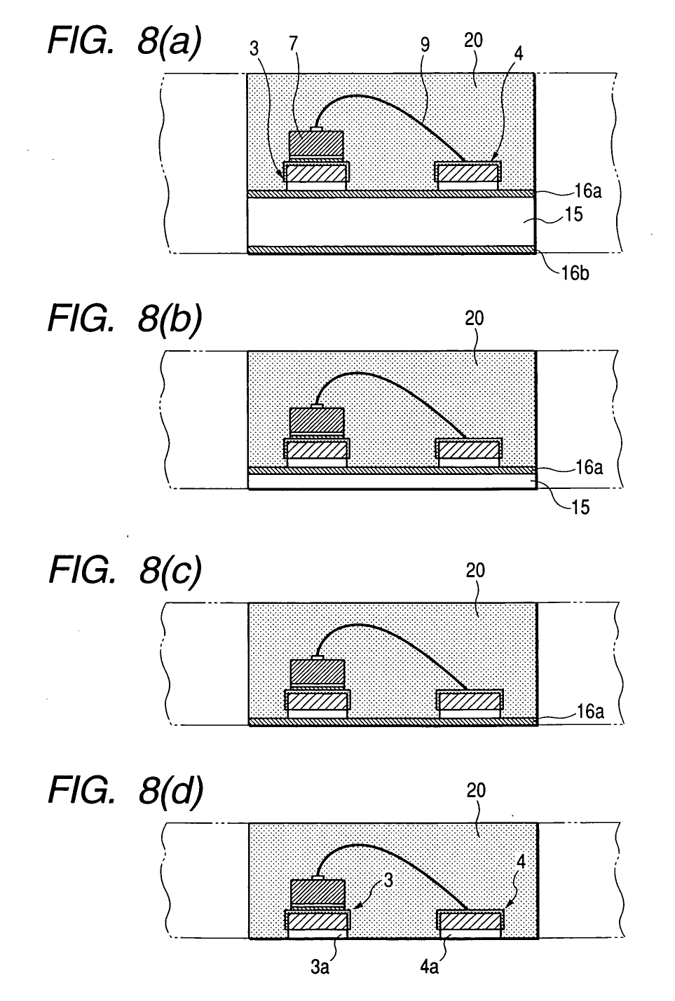

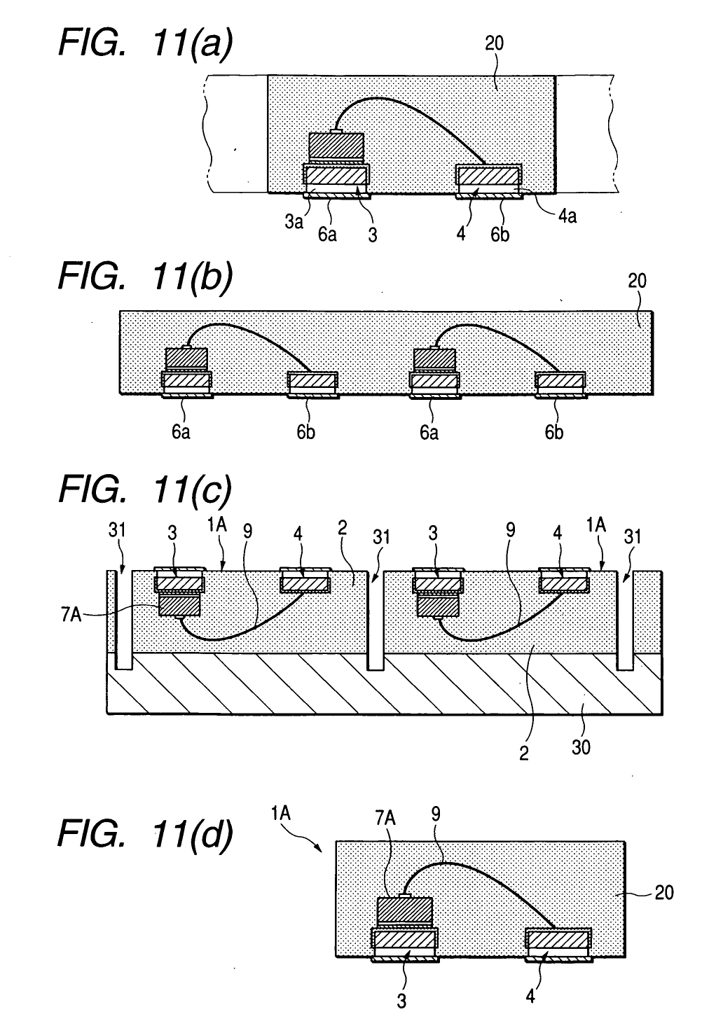

The following describes the semiconductor device (diode) manufacturing method of the present embodiment 1 with reference to FIGS. 5 to 11. FIGS. 5(a) to (f) are views from the step of preparing a silicon wafer to the step of forming metal bumps; FIGS. 7(a) to (e) are views from the step of forming a plating film on the surface of core metal layers to the step of connecting an electrode of a semiconductor element fixed on a member-mounting section with a wire-bonding section through a wire; FIGS. 8(a) to (d) are views from the step of forming a resin layer on the main face of a silicon wafer to the step of removing the wafer and a silicon oxide film on the wafer main face; and FIGS. 11(a) to (d) are views from the step of forming a mounting plating film on the rear face of a metal-laminated film exposed from the rear face of the resin layer to the step of cutting the resin layer lengthwise and breadthwise to manufacture plural semiconductor devices.

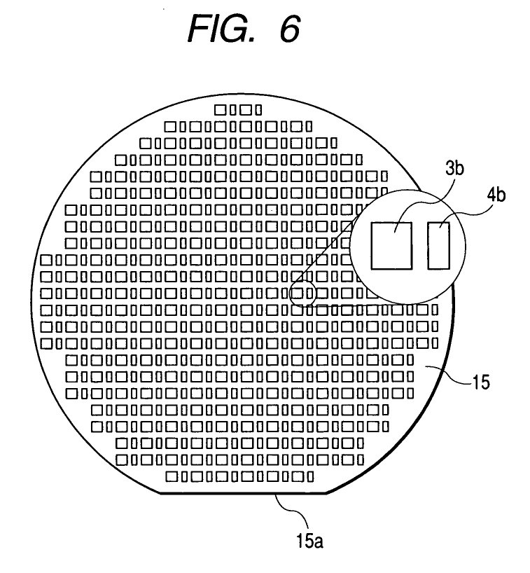

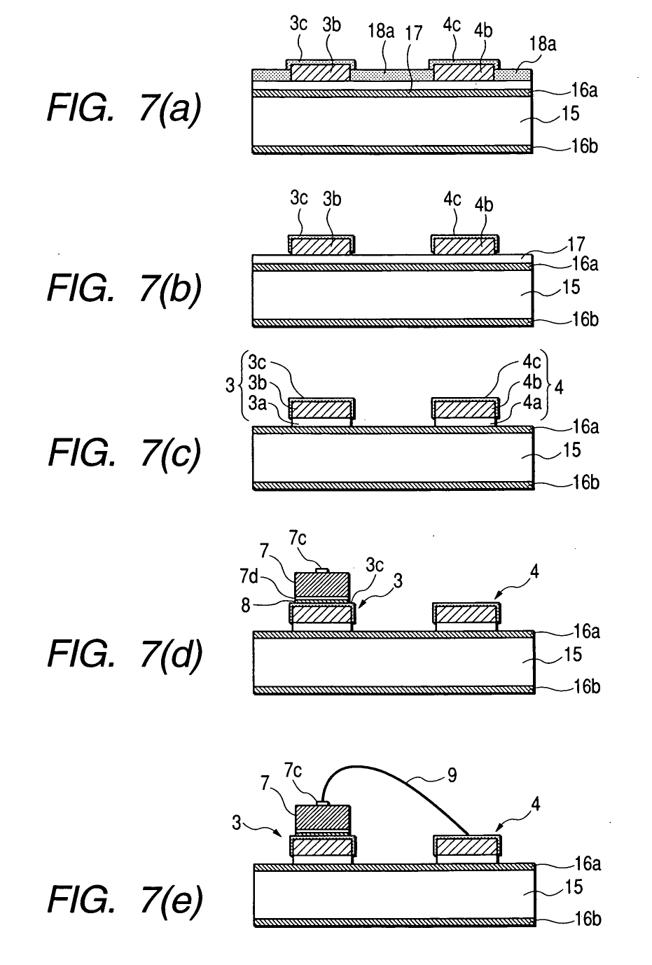

As illustrated in FIG. 5(a), a supporting substrate 15 having a large area is first used. This supporting substrate 15 is a silicon substrate (silicon wafer) 15, and is, for example, a silicon monocrystalline substrate of 600 μm thickness and 150 mm diameter. The main face and the rear face thereof are subjected to mirror-plane finishing. FIG. 6 is a schematic plan view illustrating the silicon wafer 15. The silicon wafer 15 has a standard line 15a wherein one partial periphery of the wafer is formed into a straight line form. The supporting substrate 15 may be a polysilicon substrate or a sintered substrate obtained by compressing silicon fine particles and sintering the resultant.

Next, this silicon wafer 15 is subjected to thermal oxidation treatment at 1000° C. so as to form oxide films (silicon oxide films: thermal oxidized films) 16a and 16b of, e.g. 0.8 μm thickness on the main face and the rear face of the silicon wafer 15, as described in FIG. 5(b).

Next, as illustrated in FIG. 5(c), a metal laminated-film 17 is formed on the main face of the silicon wafer 15. The metal-laminated film 17 is composed of a Ti layer, which is a lower layer, and a Ni layer formed on this Ti layer. For example, the thickness of the Ti layer is 0.3 μm and that of the Ni layer is 0.2 μm. This metal-laminated layer becomes an under-bump metal layer (UBM layer). It is desired that the thickness of this metal-laminated layer 17 is set to 0.1 μm or more so that electric current flows without any difficulty at the time of forming core metal layers 3b and 4b by electroplating in a subsequent step. The metal-laminated film 17 may be a combination of a Ti layer (lower layer) and a Au layer which have about the same thicknesses as described above. The metal-laminated layer 17 is formed e.g., by sputtering.

Next, as illustrated in FIG. 5(d), a photoresist film 18 is formed on the main face of the silicon wafer 15. The photoresist film 18 is formed by spin coating. The photoresist film 18 is made into a thickness of about 30 μm.

Next, the photoresist film 18 is exposed into a given pattern, and developed so as to be caused to remain selectively, thereby forming a mask 18a, as illustrated in FIG. 5(e).

Next, a plating layer is formed on the surface of the metal-laminated layer 17 exposed from the mask 18a by electroplating, so as to form core metal layers 3b and 4b (see FIG. 5[f]). FIG. 6 is a schematic plan view of the silicon wafer 15. A rectangular portion at the right side in a circular area enlarged and shown in the same figure is a portion which will be one out of wire-bonding sections, and a rectangular portion close to a quadrangle at the left side is a portion which will be one out of member-mounting sections 3. Such semiconductor device manufacturing portions (product-forming portions) are lined up and arranged lengthwise and breadthwise on the basis of the standard line 15a, which is a peripheral linear portion of the silicon wafer 15. Accordingly, at the final stage, the wafer is cut lengthwise and breadthwise along edges of the product-forming portions, whereby a large number of the semiconductor devices (diodes) 1A can be manufactured at a time.

In this step, the core metal layers 3b in the member-mounting sections 3 and the core metal layers 4b in the wire-bonding sections 4 are formed. The core metal layers 3b and 4b are each made of, for example, a Ni layer of 35 μm layer. The thickness of the photoresist film 18 (mask 18a) is 30 μm, and the core metal layers 3b and 4b are as thick as 35 μm; therefore, the core metal layers 3b and 4b are projected out by 5 μm from the surface of the mask 18a. The core metal layers 3b and 4b may each be a layer made of a different metal, such as Cu, instead of Ni.

Next, as illustrated in FIG. 7(a), plating films 3c and 4c are formed on the surfaces (main faces) of the core metal layers 3b and 4b, respectively, by electroplating. The plating films 3c and 4c are each composed of, for example, a Ni layer (lower layer) of 10 μm thickness and a Au layer of 0.5 μm thickness. Since the plating films 3c and 4c are formed also on circumferential faces of the core metal layers 3b and 4b, respectively, so as to be projected out by 10.5 μm from the surface of the mask 18a, these portions become thicker than the diameters of the core metal layers 3b and 4b on which no plating films 3c and 4c are formed. Thus, a structure wherein anchor effect can be obtained is formed.

Next, as illustrated in FIG. 7(b), the mask 18a is removed, and subsequently the plating films 3c and 4c and the core metal layers 3b and 4b are used as a mask to etch and remove the exposed metal-laminated layer 17. As a result, metal-laminated layer 3a and 4a are formed beneath the core metal layers 3b and 4b, respectively, so that each of the member-mounting sections 3 and each of the wire-bonding sections 4 are formed.

About the material structure of the member-mounting section 3 and the wire-bonding section 4, their main faces are Au layer, their rear faces are Ti layers and their insides are Ni layers. The structure is a Ni-Au based structure. Since the main faces are the Au layers, the structure becomes suitable for the connection of semiconductor chips or wires.

In the structure of this type, which is formed by laminating metals, the combination of Cu and Au are generally used in many cases. However, peeling strength between the metals and heat resistance (the degree of mutual diffusion between the metals) have been investigated; consequently, its has been found out that the combination of Ni and Au is optimal.

That is, it has been found out that according to investigation at a hand-soldering temperature (from 350° C. to 400° C.) at the time of mounting the semiconductor device 1A, the intermetallic mutual diffusion coefficient of Cu—Au systems is larger than that of Ni—Au systems and the Cu—Au systems are poorer in heat resistance and reliability between the metals than the Ni—Au systems since mutual diffusion proceeds in the Cu—Au systems.

Next, as illustrated in FIG. 7(d), a semiconductor chip 7A is mounted on the main face of the member-mounting section 3, strictly, on the plating film 3c. The semiconductor chip 7A has an electrode 7c on its main face and has an electrode 7d on the rear face thereof, as described above. Thus, this semiconductor chip 7A overlaps with the main face of the member-mounting section 3 across the electrode 7d, and is fixed through an electroconductive Ag paste which is beforehand applied onto the surface of the electrode 7d made of Au. The Ag paste is baked to be cured. Through this cured adhesive 8, the semiconductor chip 7A is fixed onto the member-mounting section 3.

Next, as illustrated in FIG. 7(e), the electrode 7c on the main face of the semiconductor chip 7A and the main face of the wire-bonding section 4 are electrically connected to each other through an electroconductive wire 9 made of a gold wire of 20 μm diameter.

Next, as illustrated in FIG. 8(a), the silicon wafer 15 is used as a supporting member and a commonly used transfer molding machine is used to apply a single-side molding to the main face of the supporting substrate 15, thereby forming a resin layer 20 made of an insulating resin. The resin layer 20 has a constant thickness, and is formed to extend to portions outside the outer circumferential portion of the silicon wafer 15 (package-molding). Some figures out of FIGS. 8 and 11 are views which schematically illustrate not only a manufacture portion of the single semiconductor device 1A but also both sides thereof.

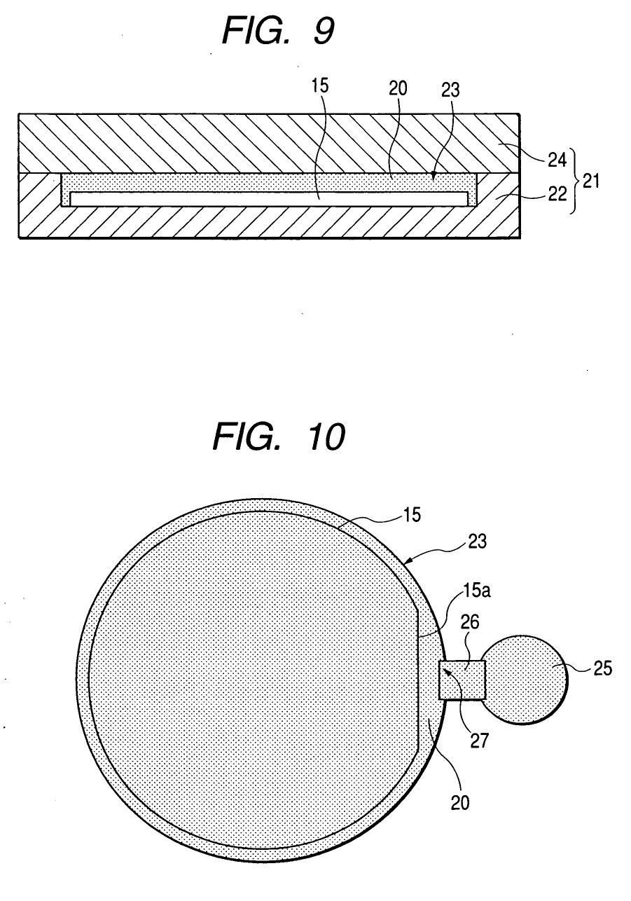

FIG. 9 is a schematic sectional view illustrating a molding die of the transfer molding machine for forming the resin-sealing layer, and others. The silicon wafer 15 subjected to chip bonding and wire bonding is put onto the bottom of a cavity 23 of a lower part 22 of the molding die 21, and subsequently an upper part 24 is put thereon so as to clamp the die. Next, an insulating resin is put into the cavity 23 by use of pressure, and further is cured for a given time to form the resin layer 20.

FIG. 10 is a schematic plan view illustrating a cull 25, a runner 26, a gate 27, and the cavity 23 made by clamping the molding die 21. The fluid resin pressed with a non-illustrated piston rod is sent out from the cull 25, and is passed through the runner 26 to be injected from the gate to the cavity 23. The injected resin is filled into the whole of the cavity 23 and further a part of the resin, together with air, is caused to flow out from a non-illustrated air vent. In this sate, the resin is cured. After the resin is cured, the die is opened to take out the resin layer 20. At this time, the resin is separated at the gate portion cured thereof, so as to dispose of resin portions cured in the cull 25 and the runner 26.

Herein, it is feared that the resin is warped on the basis of difference between the thermal expansion coefficient of the silicon wafer 15 and that of the resin layer 20 while the resin is cooled from the molding temperature of abut 180° C. to room temperature, so that transporting failure will be caused to a subsequent step. It is therefore important to select the molding resin to be used. Since any conventional ordinary transfer molding resin has a large thermal expansion coefficient of 2×10⁻⁵/° C. or more, the wafer is largely warped after the resin is molded.

Thus, in the present embodiment 1, in this package-molding, from results of investigations on the relationship between the thermal expansion coefficient of the resin layer 20 made of epoxy resin and the warp amount based on the difference thereof from the thermal expansion coefficient (α=3.5×10⁻⁶/° C.) of the silicon wafer 15, epoxy resin having a thermal expansion coefficient of 1.6×10⁻⁵/° C. or less has been used. Namely, by use of resin having such a thermal expansion coefficient, the warp amount of the resin has been able to be restrained into 0.7 mm at the time of making the resin into a cover of 0.1 mm thickness, and the warp amount of the resin has been able to be restrained into 1.2 mm at the time of making the resin into a cover of 0.4 mm thickness. In the case of forming the resin layer 20 made from a liquid resin by potting, the warp amount of the resin has been able to be restrained into 0.7 mm or less at the time of making the resin into a cover of 0.5 mm thickness. These data indicates a level which is given to no problems to ordinary transporting systems and is sufficient for the systems.

In the process up to this package-molding, the silicon wafer 15 is used as a supporting member. However, after the package-molding, the resin layer 20 is turned to a supporting member. Consequently, the process before the package-molding step, facilities for the wafer process, which is a technique that has been established hitherto, are used as they are. Since the resin layer 20 is thin also after the package-molding step, the facilities for the wafer process can be used similarly.

Next, the supporting substrate 15 and the oxide films 16a and 16b on the front and rear faces thereof are removed from the rear face of the resin layer 20. This removing work is performed in three separated steps in FIGS. 8(b) to 8(d). That is, the silicon wafer 15 is ground from its rear face side with an infield type rotary wafer grinding machine, so as to be made thin (see FIG. 8[b]), and subsequently the remaining film of silicon and the silicon oxide film 16a are removed by two chemical etchings wherein an etchant is exchanged (see FIGS. 8[c] and [d]). In the first etching, the silicon is etched and removed with a hydrofluoric acid type etchant, and in the second etching, the silicon oxide film (SiO₂ film) 16a is etched and removed with an alkaline etchant. In this way, the rear faces of the member-mounting section 3 and the wire-bonding section 4, i.e., the rear faces of the metal-laminated films 3a and 4a are exposed to the rear face of the resin layer 20.

In order to maintain uniformity for etching in the wafer surface, the amount of grinding was made into 560 μm so as to set the thickness of the silicon-remaining film, after being ground, would be 50 μm. The rate that the silicon oxide film 16a is etched with a chemical etchant at the time of spin etching is several times smaller than that of silicon; therefore, the silicon oxide film 16a acts as a stopper of etching (see FIG. 8[c]). Thus, the margin for the work can be sufficiently taken.

As described above, chemical etching is performed by use of the silicon oxide film 16a on the main face of the silicon wafer 15 as an etching stopper, and subsequently the remaining silicon oxide film 16a is chemically etched, thereby making it possible to prevent damage of the Ti layer on the rear face of the member-mounting section 3 or the wire-bonding section 4 or the Ni layer of the layer thereon, the damage being based on excessive etching.

In order to make the lifespan of the grinding blade of the wafer grinding machine long, it is allowable to etch and remove the silicon oxide film 16a on the rear face of the silicon wafer 15 and subsequently grind the resultant.

By performing the removing work of the silicon wafer 15 by mechanical grinding and chemical etching as described above, the time for the work can be made short and the working treatment can be made highly precise. In addition, the removing work contributes to the manufacture of a semiconductor device high in reliability.

Next, as illustrated in FIG. 11(a), by electroless plating, mounting plating films 6a and 6b are formed on the rear faces of the metal-laminated films 3a and 4a, respectively, exposed to the rear face of the resin layer 20. By this electroless plating, a Ni film is formed into a thickness of 10 μm on the surface of the metal-laminated films 3a and 4a and further a Au film is formed into a thickness of 0.5 μm on this Ni film. In the present embodiment 1, the rear face side of each of the member-mounting section 3 and that of each of the wire-bonding section 4 become external electrode terminals.

The rear faces of the member-mounting section 3 and wire-bonding section 4 and the rear face of the resin layer 20 are positioned on substantially the same plane. Therefore, the resultant external electrode terminals come to have a standoff structure by the formation of the mounting plating films 6a and 6b.

Next, electrical characteristics thereof are examined. As illustrated in FIG. 11(b), the member-mounting sections 3 as the external electrode terminals and the wire-bonding sections 4 are exposed in the form of islands from the rear face of the wafer-form resin layer 20. Therefore, a probe card and a prober are used to conduct the electrical characteristic examination in a lump in the same way as in the probe test of ordinary semiconductor wafers.

Next, as illustrated in FIG. 11(c), a resin sheet 30 for dicing is stuck onto the main face of the resin layer 20. On the basis of the layout arrangement of the mounting plating films 6a and 6b on the rear face (the face which is directed upwards in the figure), separating grooves 31 are made lengthwise and breadthwise from the rear face of the resin layer 20 to a middle depth of the resin sheet 30 by means of a dicing blade, so as to make the resin layer 20 into individual pieces. The resin layer 20 made into the individual pieces constitute semiconductor devices 1A. However, in this state, each of the semiconductor devices 1A sticks onto the resin sheet 30. When the resin layer 20 is made into the individual pieces, the resin layer 20 becomes a sealant 2.

Next, the semiconductor devices 1A are peeled from the resin sheet 30, so as to produce each semiconductor device 1A, which is illustrated in FIGS. 11(d), and FIGS. 1 and 2.

The resin sheet 30 is a transparent tape the adhesive force of which is made small by irradiation with ultraviolet rays (UV), and has, for example, a structure wherein an adhesive and a peeling agent are successively laminated on one surface of a substrate. The substrate is a polyolefin of 80 μm thickness. The adhesive is an acrylic resin of 10 μm thickness, and the peeling agent is a polyester of 38 μm thickness.

By irradiation with ultraviolet rays (illuminace: 120 mW/cm² or more, and luminous power: 70 mJ/cm² or more) after the resin layer 20 is stuck, the adhesive power thereof abruptly becomes smaller from 550 (g/25 mm) before the irradiation to 64 (g/25 mm). Therefore, when the resin sheet 30 is peeled from the resin layer 20, the resin sheet 30 can easily be peeled from the resin layer 20 by making the adhesive force small by the radiation of the resin sheet 30 with the ultraviolet rays. In respective embodiments which will be described later, this manner is adopted for the peeling of their resin sheet 30 from their resin layer 20.

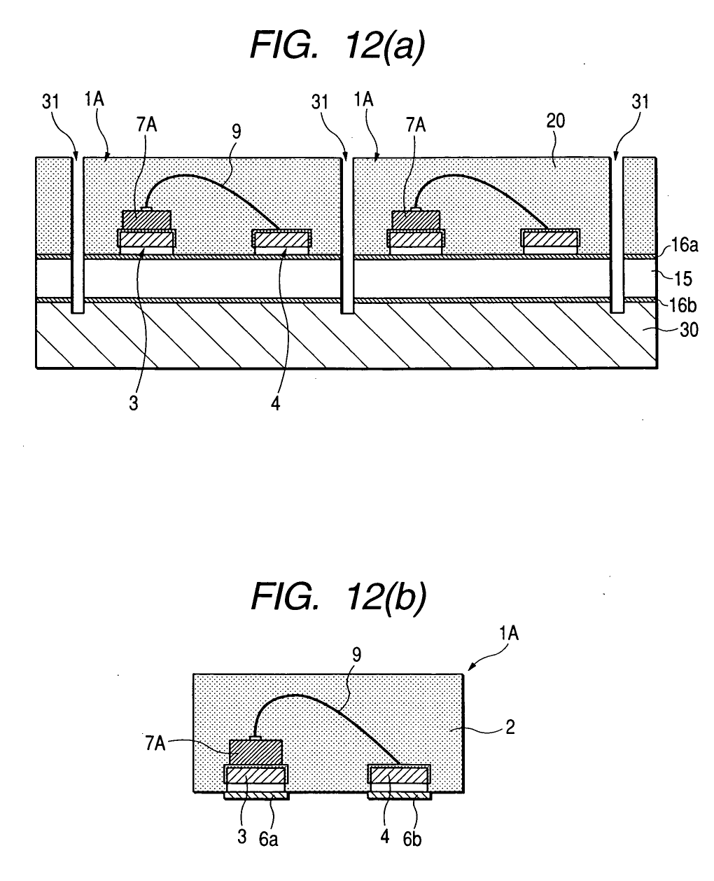

FIGS. 12 are schematic sectional process charts illustrating another example wherein a resin sealing layer is made into individual pieces in the semiconductor device manufacturing method in the present embodiment 1. In the figures, electrodes on the main face and the rear face of a semiconductor chip 7A are omitted, and an adhesive for fixing the semiconductor chip 7A is also omitted. The omission is performed in the same way as in the respective embodiments which will be detailed later.

In this example, as illustrated in FIG. 12(a), a resin layer 20 is formed on the main face of a silicon wafer 15, and subsequently a resin sheet 30 is stuck onto the rear face of the silicon wafer 15. Separating grooves 31 are then made lengthwise and breadthwise from the main face of the resin layer 20 to a middle depth of the resin sheet 30 by means of a dicing blade, so as to make the resin layer 20 into individual pieces. In this way, semiconductor devices 1A are formed.

Next, the semiconductor devices 1A onto which the supporting substrate 15 stick are peeled from the resin sheet 30, and further their oxide film 16b, supporting substrate 15 and oxide film 16a are successively removed by etching or the like, so as to expose the rear faces of the member-mounting sections 3 and the wire-bonding sections 4 to the rear face of a sealant 2.

Thereafter, as illustrated in FIG. 12(b), mounting plating films 6a and 6b are formed on the rear faces of the member-mounting sections 3 and the wire-bonding sections 4 exposed to the rear face of the sealant 2 by an electroless plating or barrel plating method. In this way, the semiconductor devices 1A are manufactured.

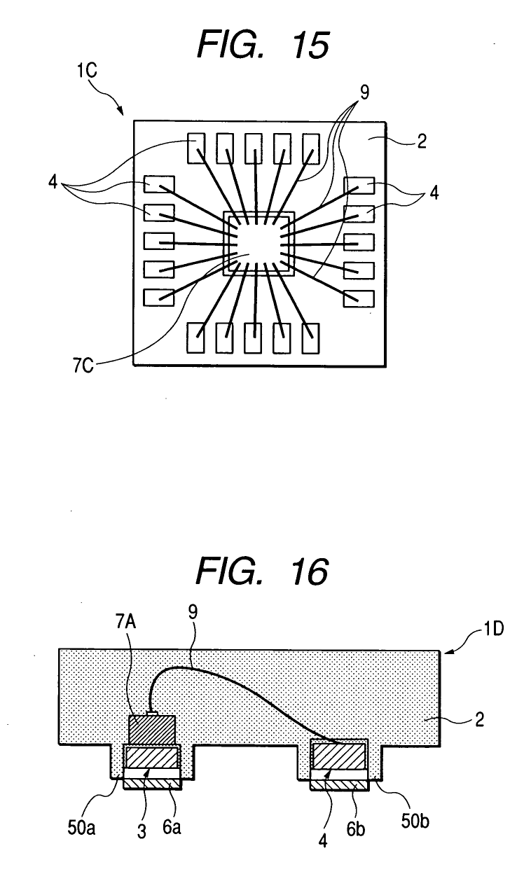

In the present embodiment 1, semiconductor devices having a further different structure can be manufactured by selecting the sizes of the member-mounting sections 3 or the wire-bonding sections 4, selecting the arrangement position thereof (changing the pattern), or selecting semiconductor devices to be mounted. FIGS. 14 and 15 are see-through plan views illustrating examples of different semiconductor devices.

FIG. 14 is one of the schematic see-through plan views, which illustrates a semiconductor device 1B (transistor) manufactured by the semiconductor device manufacturing method of the present embodiment 1. As illustrated in FIG. 14, the semiconductor device 1B has a structure in which a member-mounting section 3 is arranged at the left side in a sealant 2 made of a rectangular solid and two wire-bonding sections 4 are arranged at the right side. A semiconductor element 7B into which a transistor is integrated is fixed onto the main face of the member-mounting section 3. In the semiconductor element 7B, an electrode is formed on the rear face thereof. This electrode is fixed through an electroconductive jointing material onto the member-mounting section 3. Two electrodes, which are not illustrated, are formed on the main face of the semiconductor element 7B. These electrodes are connected through electroconductive wires 9 to the wire-bonding sections 4. The relationship between the sealant 2 and the member-mounting section 3, the wire-bonding sections 4, the semiconductor element 7B and the wires 9 is the same as in the semiconductor devices 1A in the embodiment 1.

FIG. 15 is one of the schematic see-through plan views, which illustrates an IC manufactured by the semiconductor device manufacturing method of the present embodiment 1. As illustrated in FIG. 15, the semiconductor device (IC) 1C of this example has a structure in which in a sealant 2 made of a rectangular solid, a member-mounting section 3 is arranged at the center thereof and small wire-bonding sections 4 are arranged along each of the quadrangle. A semiconductor element 7C into which the IC (integrated circuit device) is integrated is fixed onto the main face of the member-mounting section 3. The semiconductor element 7C is fixed, at the rear face thereof, through a jointing material onto the member-mounting section 3. Plural electrodes, which are not illustrated, are fitted to the periphery of the main face of the semiconductor element 7C. These electrodes are each connected through electroconductive wires 9 to the wire-bonding sections 4. The relationship about the sealant 2 and the member-mounting section 3, the wire-bonding sections 4, the semiconductor element 7B and the wires 9 is the same as in the semiconductor devices 1A in the embodiment 1.

It is allowable to fix the silicon substrate which forms the semiconductor element 7C through an insulating jointing material onto the member-mounting section 3, or to fix the silicon substrate through an electroconductive jointing material onto the member-mounting section 3 and use this member-mounting section 3 also as an external electrode terminal. Since the member-mounting section 3 is exposed to the rear face of the sealant 2, the section can be used as a heat-spreading plate for radiating heat generated from the IC.

According to the present embodiment 1, the following advantageous effects are produced.

(1) Since the silicon wafer 15, which is a semiconductor substrate, is used as a supporting member and this supporting member and the oxide film 16b formed between the supporting member and the resin section are removed in the latter half stage of the manufacture, the manufactured semiconductor device can be made thin. For example, a thin semiconductor device of 0.5 mm or less thickness can be manufactured.

(2) Since the resin layer 20 is formed in a package-molding manner and subsequently this resin layer 20 is cut lengthwise and breadthwise to manufacture a semiconductor device, the semiconductor device can be made small-sized.

(3) Since the silicon wafer 15, for which facilities for the established wafer process can be used, is used as a supporting member to manufacture semiconductor devices, the devices can be manufactured with a high precision and a high yield. Thus, costs of the semiconductor devices can be made low. In other words, in the step up to the package-molding step, the silicon member 15 functions as a supporting member while after the package-molding step the resin layer 20 functions as a supporting member; therefore, in the steps before the package-molding step, facilities for the wafer process, which is a technique that has been established hitherto, can be used as they are. After the package-molding step, the facilities for the wafer process can be used in the same way since the resin layer 20 is thin.

(4) Since the package-molding manner is adopted, it is unnecessary to prepare molding dies in accordance with packages of individual products and it is sufficient that a molding die corresponding to the size of a silicon wafer is prepared. Thus, the facilities have flexibility for varieties or kinds different in shape or the number of external electrode terminals. Investment and costs of the dies and others can be made minimum.

(5) Since the semiconductor device is thin and small-sized, the device is excellent in low inductance property so as to be suitable for high frequency circuits.

(6) Since the rear face of the metal pedestals has a standoff structure wherein the rear face is projected from the rear face of the sealant 2, mounting failure based on the interposition of foreign substances is not easily caused at the time of mounting.

(7) Since the metal pedestals are positioned inside the peripheral edge of the sealant 2, a short circuit between the pedestals and electronic members adjacent thereto when the members are mounted is not easily caused.

(8) Since the front ends of the metal pedestals are thick inside the sealant, the metal pedestals, that is, the external electrode terminals do not fall easily from the sealant 2. Thus, the reliability of the semiconductor device becomes high.

(9) Since the metal pedestals connected directly to the external electrode terminals are positioned just below semiconductor chips, which are heat-generating bodies, a semiconductor device excellent in heat-radiating property is manufactured.

(10) Since the metal pedestals are made of a ferromagnetic substance, the semiconductor device can be subjected to transporting or delivering treatment using magnetism. For example, in process for classifying characteristics of the semiconductor device, stamping process or packaging process, the semiconductor device can be subjected to transporting or delivering work using magnetism. Thus, the manufacture costs of the semiconductor device can be reduced.

(11) The metal pedestals are made of combination of Ni with Au, and are good in peeling strength between the metals and heat resistance (the degree of intermetallic mutual diffusion). Thus, the reliability of the semiconductor device is improved.

(12) In the manufacture of the semiconductor device, epoxy resin having a thermal expansion coefficient of 1.6×10⁻⁵/° C. or less is used to form the resin layer 20 on the main face of the silicon wafer 15. Accordingly, the wafer is warped to a small extent after the wafer is transfer-molded. Thus, no troubles are given to a transporting system, and the working power thereof is not hindered. For example, by use of a resin having such a thermal expansion coefficient, the warp amount can be controlled into 0.7 mm when the resin is made into a cover of 0.1 mm thickness, and the warp amount can be controlled into 1.2 mm when the resin is made into a cover of 0.4 mm thickness. In the case that liquid resin is made into the resin layer 20 by potting, the warp amount can be controlled into 0.7 mm or less when the resin is made into a cover of 0.5 mm thickness. These data keep a level which is given to no problems to ordinary transporting systems and is sufficient for the systems.

(13) When the silicon wafer 15 having the oxide films 16a and 16b is removed from the resin layer 20 after the end of fabrication on the main face side of the silicon wafer 15 and the formation of the resin layer, they are removed by mechanical grinding and chemical etching. In this removal, the oxide film 16a is used as an etching stopper and subsequently this oxide film 16a is etched. It is therefore possible to prevent damage of the Ti layers on the rear faces of the member-mounting sections 3 or the wire-bonding sections 4, or the Ni layers on the Ti layers, the damage being based on excessive etching. By performing the removing operation of the silicon wafer 15 by mechanical grinding and chemical etching as described above, the time for the work can be made short and a high-precision working treatment can be attained. Additionally, a semiconductor device having a high reliability can be manufactured.

(14) Since the external electrode terminals in the form of islands are exposed to the rear face of the wafer-form resin layer 20, in the electrical characteristic examination a probe card and a prober are used to process the electrical characteristic examination in a lump in the probe test of ordinary semiconductor wafers. Thus, the time for the measurement can be made short and the manufacture costs of the semiconductor device can be decreased.

(15) More various semiconductor devices can be manufactured by selecting the sizes of the member-mounting sections 3 or the wire-bonding sections 4, selecting the arrangement positions thereof (changing the pattern), or selecting semiconductor to be mounted.

### Embodiment 2

FIGS. 16 to 19 are views concerned with a semiconductor device (diode) which is a different embodiment (embodiment 2) of the present invention, and a manufacturing method thereof. The semiconductor device 1D of the present embodiment 2 is an example wherein the standoff amount in the semiconductor device 1A of the embodiment 1 is made large. Therefore, the device has a structure wherein the rear face of a sealant 2 is projected, at two positions thereof, into a rectangular form (projected portions 50a and 50b); a member-mounting section 3 is arranged at the center of the projected portion 50a; and a wire-bonding section 4 is arranged at the center of the other projected portion 50b. The projection length of the projected portions 50a and 50b is, for example, 40 μm. Since mounting plating films 6a and 6b on the rear face sides of the member-mounting section 3 and the wire-bonding section 4 have a thickness of 10.5 μm, the semiconductor device 1D is a device wherein the distance from the rear face of the sealant 2 to the rear faces of the member-mounting section 3 and the wire-bonding section 4 is 50.5 μm, and the standoff amount is 40 μm larger than that of the semiconductor device 1A of the above-mentioned embodiment 1.

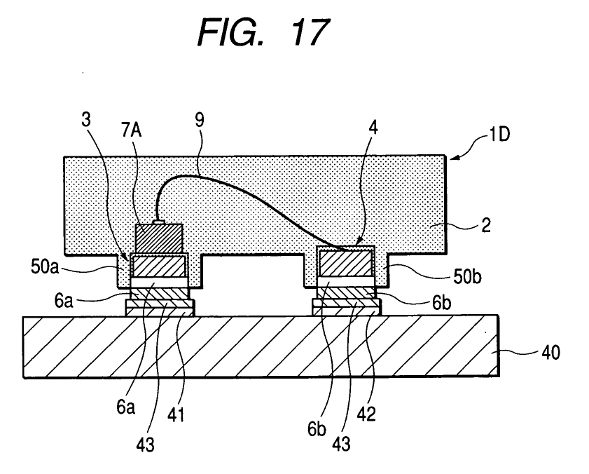

FIG. 17 is a schematic sectional view illustrating a mounting state of the semiconductor device 1D. In the main face of a mounting substrate 40, lands 41 and 42 corresponding to the member-mounting section 3 and the wire-bonding section 4 of the semiconductor device 1D are formed. The member-mounting section 3 and the wire-bonding section 4 are positioned and fixed, through an adhesive 43 such as solder, onto the lands 41 and 42, respectively.

In this semiconductor device 1D, the distance between the main face of the mounting substrate 40 and the rear face of the sealant 2 on which the projected portions 50a and 50b are not formed is as wide as, for example, 50.5 μm, so that a sufficient standoff amount is kept. Therefore, even if an foreign substance comes in between the main face of the mounting substrate 4 and the rear face of the sealant 2, the member-mounting section 3 and the wire-bonding section 4 are surely connected to the lands 41 and 42, respectively, as far as the foreign substance is not very large. Thus, the reliability of the mounting becomes high.

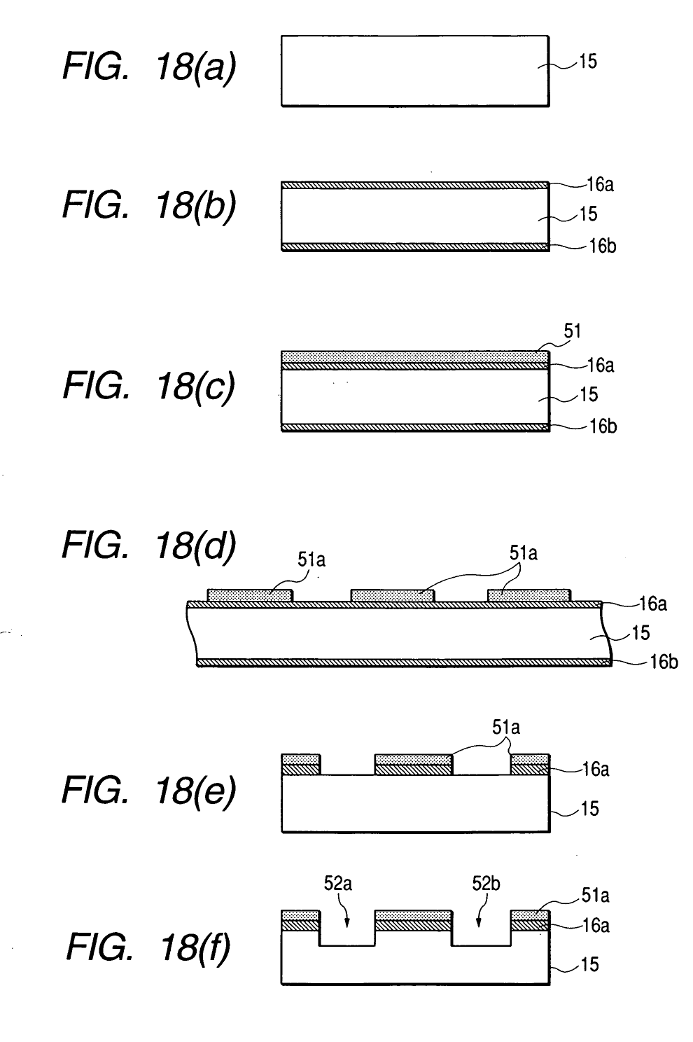

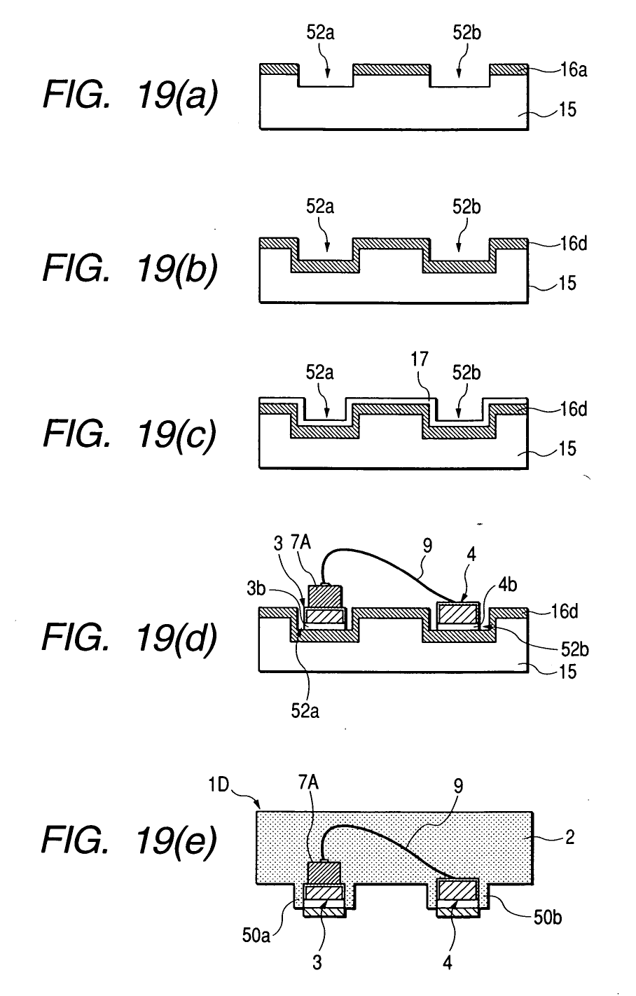

The following describes the production of the semiconductor device (diode) 1D of the present embodiment 2. As illustrated in FIG. 18(a), a silicon wafer 15 is prepared, and then oxide films (silicon oxide films) 16a and 16b are formed on the main face and the rear face of the silicon wafer 15, respectively (see FIG. 18[c]).

Next, as illustrated in FIG. 18[c], a photoresist film 51 is formed on the main face of the silicon wafer 15, and subsequently this photoresist film 51 is formed into a given pattern as illustrated in FIG. 18(d), thereby forming a mask 51a. Next, this mask 51a is used as an etching mask to etch and remove the surface layer portion on the main face side of the oxide film 16a and the silicon wafer 15 by a given thickness (for example, a little more than 40 μm), thereby forming rectangular hollows 52a and 52b (see FIGS. 18[e] and [f]). The mask 51a has the same pattern as the mask 18a in the embodiment 1. When the oxide film 16a is removed by this etching, the oxide film 16b on the rear face of the silicon wafer 15 is simultaneously removed.

Next, the mask 51a (photoresist film 51) is removed (see FIG. 19[a]), and subsequently the main face of the silicon wafer 15 is oxidized to form a silicon oxide film 16d, as illustrated in FIG. 19(b). The oxide film 16a is integrated with the silicon oxide film 16d, so as to be made into the film 16d. At this stage, the depth of the hollows 52a and 52b is 40 μm.

Next, as illustrated in FIG. 19(c), a metal-laminated film 17 composed of a Ti layer (subjacent layer) and a Ni layer is formed in the same way as in the embodiment 1. The thickness of this metal-laminated film 17, which will be an under-bump metal layer, is 0.5 μm. This state corresponds to the state of FIG. 5(c) in the case of the embodiment 1. Different points are that the hollows 52a and 52b are present in the main face 42. of the silicon wafer 15 and no silicon oxide film is present on the rear face.

Next, as illustrated in FIG. 19(d), member-mounting sections 3 and wire-bonding sections 4 are formed on the bottoms of the hollows 52a and the hollows 52b, respectively. During the term from the step illustrated in FIG. 19(c) to the step illustrated in FIG. 19(d), the processings illustrated in FIGS. 5(d) to 5(f) and FIGS. 7(a) to 7(d) are successively performed. That is, the following are performed: the formation of a mask on the main face of the silicon wafer 15; the formation of core metal layers 3b and 4b by use of this mask; the formation of plating films 3c and 4c having anchor effect on the main faces of the core metal layers 3b and 4b; and the formation of the metal-laminated films 3a and 4a by selective etching of the metal-laminated film 17: By these steps, the member-mounting sections 3 and the wire-bonding sections 4 are formed on the bottoms of the hollows 52a and 52b.

Next, as illustrated in FIG. 19(d), semiconductor chips 7A are mounted on the main faces of the member-mounting sections 3. Next, an electrode 7c on the main face of each of the semiconductor chip. 7A is connected to the main face of each of the wire-bonding sections 4 through a wire 9.

Next, the working processings illustrated in FIGS. 8(a) to 8(d) and FIGS. 11(a) to 11(c) in the embodiment 1 are performed, which is not illustrated, so as to manufacture a semiconductor device 1D illustrated in FIGS. 19(e) and 16. In other words, the semiconductor device 1D is manufactured by the formation of a resin layer on the main face of the silicon wafer 15, removal of the silicon wafer 15 and the silicon oxide film 16d from the resin layer, the formation of plating films 3c and 4c on the rear faces of the member-mounting sections 3 and the wire-bonding sections 4, the faces being exposed to the rear face of the resin layer; and division of the resin layer into individual pieces.

In the semiconductor device 1D manufactured by the semiconductor device manufacturing method of the present embodiment 2, the standoff amount of the external electrode terminals is large; therefore, in the case that the semiconductor device 1D is mounted on a mounting substrate, the following is caused even if an foreign substance comes in between the mounting substrate and the sealant 2: the member-mounting sections 3 and the wire-bonding sections 4 are surely connected to lands of the mounting substrate, respectively, as far as the foreign substance is not very large.

The present embodiment 2 also has some of the advantageous effects which the embodiment 1 has.

### Embodiment 3

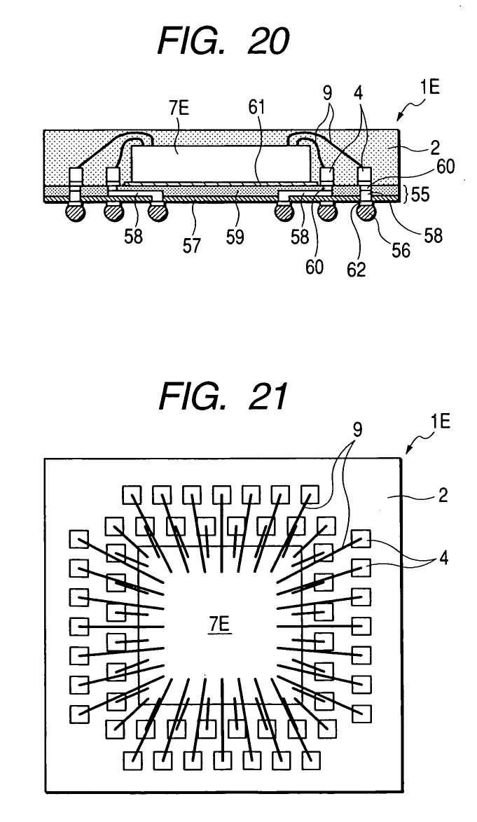

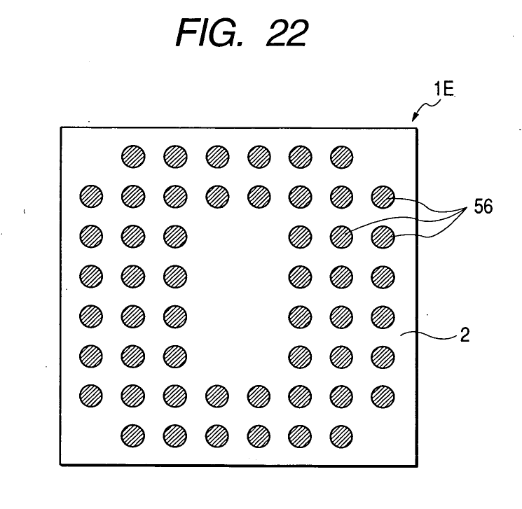

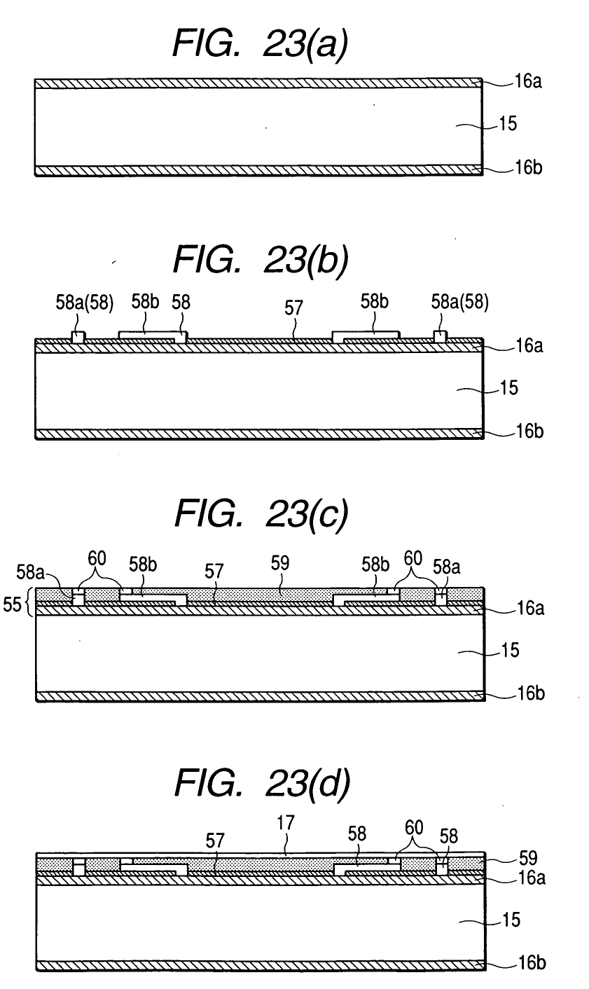

FIGS. 20 to 26 are views concerned with a semiconductor device which is a different embodiment (embodiment 3) of the present invention, and a manufacturing method thereof, in which FIGS. 20 to 22 are views concerned with the semiconductor device, and FIGS. 22 to 26 are views concerned with the semiconductor device manufacturing method.

The present embodiment 3 and embodiments subsequent thereto have a structure wherein a wiring region (multi-layered wiring region) is made of an insulating film and an electroconductive layer on the main face of a silicon wafer 15, and metal pedestals, that is, member-mounting sections, wire-bonding sections and electrode fixing sections are formed on the wiring of the topmost layer, whereby semiconductor chips having a larger number of electrodes can be mounted or many electronic members can be mounted. There is a structure wherein electrodes of a semiconductor chip are connected to a wire-bonding section through a wire, or a structure wherein the electrodes are connected to an electrode fixing section in a flip chip manner. In a chip member having electrodes on both ends thereof, the electrodes on both the ends are connected to a pair of electrode fixing sections.

The present embodiment 3 is an example wherein the present invention is applied to a BGA (ball grid array) type semiconductor device. A BGA (semiconductor device) 1E has a structure illustrated in FIGS. 20 to 22. FIG. 20 is a schematic sectional view of the BGA 1E, FIG. 21 is a schematic see-through plan view of the BGA 1E, and FIG. 22 is a schematic bottom view of the BGA 1E.

As illustrated in these figures, a multi-layered wiring region 55 is formed on the rear face (the lower face in FIG. 20) of a flat quadrilateral sealant 2 made of an insulating resin. Ball electrodes 56 are formed in an array form on the rear face of the multi-layered wiring region 55 (see FIG. 22). A semiconductor chip 7E is fixed through an adhesive 8 onto the center of the main face of the multi-layered wiring region 55. Electrodes, which are not illustrated, are formed on the main face of this semiconductor chip 7E. The electrodes are connected electrically to wire-bonding sections 4 formed on the main face of the multi-layered wiring region 55 through wires 9, as illustrated in FIG. 21. The wire-bonding sections 4 are each connected electrically to given one out of the ball electrodes 56 through the wiring of the multi-layered wiring region 55.

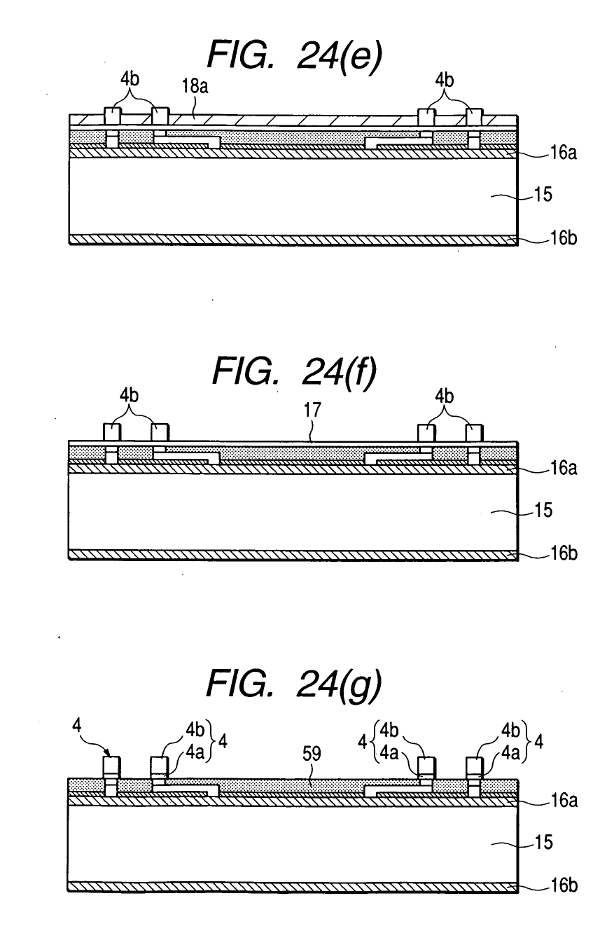

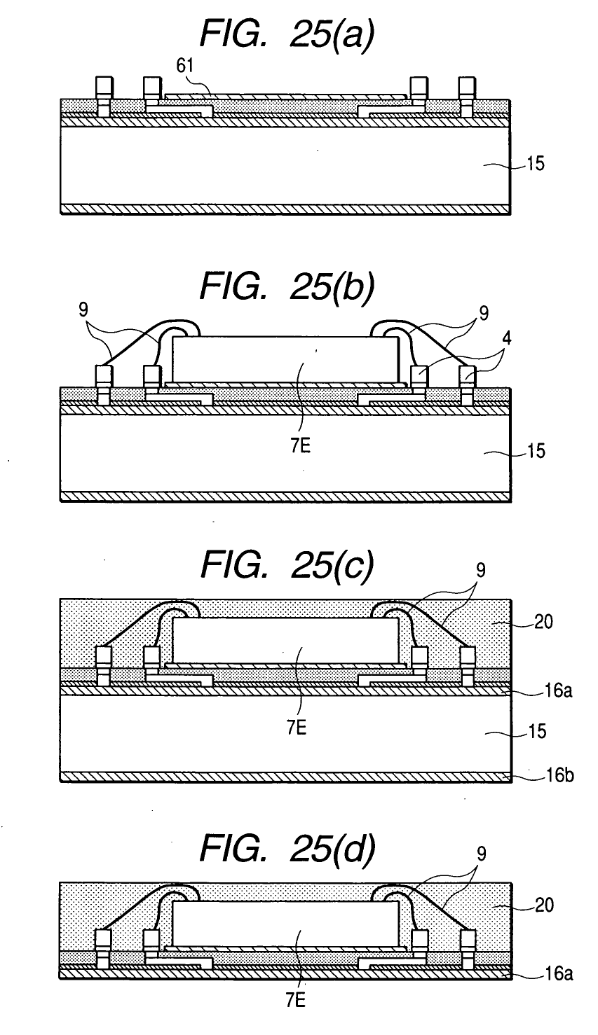

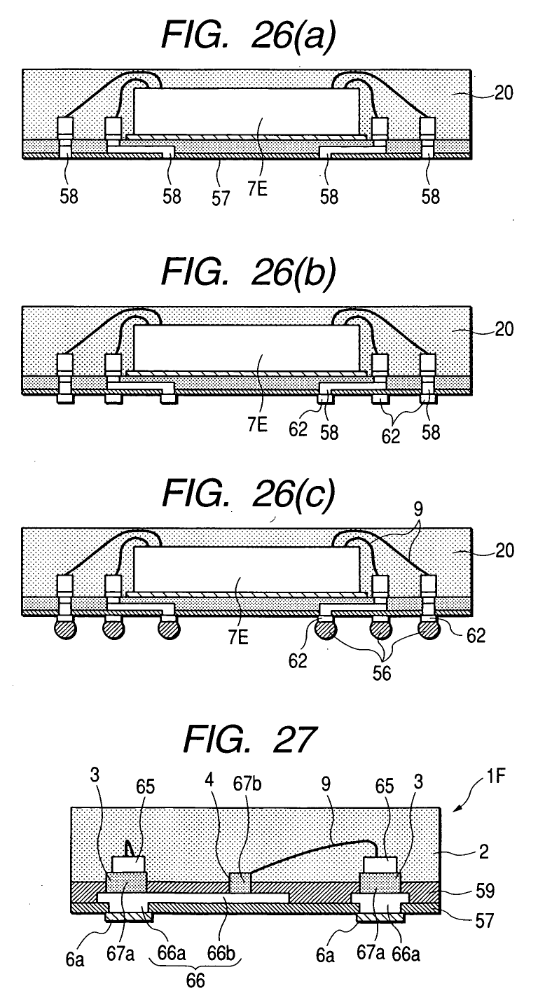

The following describes the manufacturing method of the semiconductor device 1E of the present embodiment 3 with reference to FIGS. 23 to 26. FIGS. 23 are schematic sectional process charts illustrating a process from the step of forming an oxide film on the surface of a silicon wafer to the step of forming a metal-laminated film; FIGS. 24 are schematic sectional process charts illustrating a process from the step of forming a photoresist film to the step of patterning the metal layer; FIGS. 25 are schematic sectional process charts illustrating a process from the step of applying a chip-sticking insulating paste to the step of removing the wafer; and FIGS. 26 are schematic sectional process chart illustrating a process from the step of removing the silicon oxide film on the rear face of the resultant resin sealing layer to the step of cutting the resin sealing layer lengthwise and breadthwise to make the processed wafer into individual pieces, thereby forming plural semiconductor devices. In the production of the semiconductor device 1E, a silicon wafer having a large area is used; however, only a region where the single semiconductor device 1E is manufactured is illustrated in the figures.

As illustrated in FIG. 23(a), oxide films 16a and 16b are formed on the main face and the rear face of a silicon wafer 15, respectively, by thermal oxidization in the same way as in the embodiment 1. Thereafter, as illustrated in FIG. 23(b), a first insulating film 57 is formed. In a subsequent step, the oxide film 16 will be etched, and the first insulating film 57 is made of a material that will not be etched or removed together or will not easily etched at this etching time, and is made of, for example, a photosensitive wafer coating material for re-wiring.

Next, as illustrated in FIG. 23(b), through holes are made in areas where balls electrodes 56 are to be formed by commonly used photolithographic technique and etching technique. Next, first wiring layers 58 are formed into a given pattern. An electric conductor is formed to overlap with on the first wiring layers 58, and one end of each wire will be connected thereto. The first wiring layers 58 are classified into layers formed in the through holes regions (independent regions 58a) and layers extended from the through hole regions to the first insulating film 57 (the tips thereof are called extended portions 58b). The wires will be connected to the independent regions 58a or the extended portions 58b.

The wiring extended from the through holes onto the first insulating film 57 becomes an interlayer wiring layer. Thus, the positions of the balls electrodes 56, which are external electrode terminals, can be selected at will. The first wiring layers 58 are formed by depositing a film by sputtering or the like and then forming the film into a given pattern by commonly used photolithographic technique and etching technique. In the same way, subsequent formation of respective patterns will be performed by photolithographic technique and etching technique.

Next, a second insulating film 59 is formed on the whole of the main face of the silicon wafer 15, and then through holes are made in given areas of this second insulating film 59. Furthermore, a conductor is filled into the through holes to form second wiring layers 60 (see FIG. 23[c]). In this way, a multi-layered wiring region 55 is formed.

Next, as illustrated in FIG. 23(d), a metal-laminated film 17 is formed in the same way as in the embodiment 1. Thereafter, as illustrated in FIG. 24(e), a mask 18a is formed in the same way as in the embodiment 1. However, the pattern thereof is different from that of the mask in the embodiment 1. Next, core metal layers 4b are formed on the metal-laminated film 17 by electroplating. The core metal layers 4b are formed on the independent regions 58a and the extended portions 58b of the first wiring layers 58 so as to have sizes larger than those of the second wiring layers 60. Since anchor effect can be produced in this way, subsequent formation of a plating film as performed in the embodiment 1 is not performed. However, subsequent formation of a plating film may be performed in order to improve the reliability of wire connection. The bore metal layers 4b are made of Ni in the same manner as in the embodiment 1, but may be Au plating films in order to improve the wire connection reliability.

Next, as illustrated in FIG. 24(f), the mask 18a is removed, and then the core metal layers 4b are used as a mask to etch the metal-laminated film 17, thereby forming metal-laminated films 4a as illustrated in FIG. 24(g). In this way, wire-bonding sections 4 are formed.

Next, as illustrated in FIG. 25(a), a chip-sticking insulating paste 61 is applied onto the center of the main face of the silicon wafer 15, that is, the second insulating film 59. Thereafter, each semiconductor chip 7E is fixed through this chip-sticking insulating paste 61 onto the film 59 (see FIG. 25[b]). The chip-sticking insulating paste 61 is baked for a given time to be cured.

Next, as illustrated in FIG. 25(b), electrodes of the semiconductor chip 7E are connected to the wire-bonding section 4 around the semiconductor chip 7E through wires 9.

The process after this is substantially the same as in the embodiment 1. That is, next, in the same way as in the embodiment 1, the silicon wafer 15 is used as a supporting member and an ordinary used transfer molding machine is used to subject the main face of the supporting substrate 15 to single face molding, thereby forming a resin layer 20 made of an insulating resin. The resin layer 20 has a constant thickness, and is formed to extend to portions outside the outer circumferential portion of the silicon wafer 15 (package-molding).

Next, as illustrated in FIG. 25(d), the oxide film 16b and the supporting substrate 15 are removed from the rear face of the resin layer 20 by grinding and etching. The etching of the silicon is conducted with a hydrofluoric acid type etchant. At this time, the oxide film 16b acts as an etching stopper. Next, the silicon oxide film (SiO₂ film) 16a is etched and removed with an alkaline etchant. In this way, the rear faces of the first wiring layers 58 are exposed to the rear face of the resin layer 20 (FIG. 26(a)).

Next, as illustrated in FIG. 26(b), a plating film 62 is formed on the rear faces of the first wiring layers 58 exposed to the rear face of the resin layer 20 by electroless plating. This step is different from the embodiment 1. By this electroless plating, a Au film is formed into a thickness of 0.5 μm on the surfaces of the first wiring layers. Since the rear faces of the first wiring layers 58 and the rear face of the resin layer 20 are positioned on substantially the same plane, by the formation of the plating film 62, the resultant external electrode terminals come to have a standoff structure.

Next, the resultant device is subjected to electrical characteristic examination, and a given position in the main face of the resin layer 20 is marked.

Next, ball electrodes 56 are formed by attaching solder balls onto the surface of the plating film 62. This step is different from the embodiment 1. Furthermore, the resin layer 20 is cut lengthwise and breadthwise to produces sealants 2. In this way, plural semiconductor devices (BGA) 1E are manufactured.

The present embodiment 3 has an advantageous feature that the positions of the external electrode terminals can be selected at will since the embodiment has a structure using the interlayer wiring layer.

According to the present embodiment 3, an IC having many functions can easily be made into a BGA and further a thin and inexpensive semiconductor device can be manufactured.

The present embodiment 3 also has some of the advantageous effects which the embodiment 1 has.

### Embodiment 4

FIGS. 27 to 29 are views concerned with a semiconductor device which is a different embodiment (embodiment 4) of the present invention. The present embodiment 4 is an example wherein the semiconductor device manufacturing method of the present invention is applied to a DBM (double balanced mixer) used in a converter of a CATV (cable television).

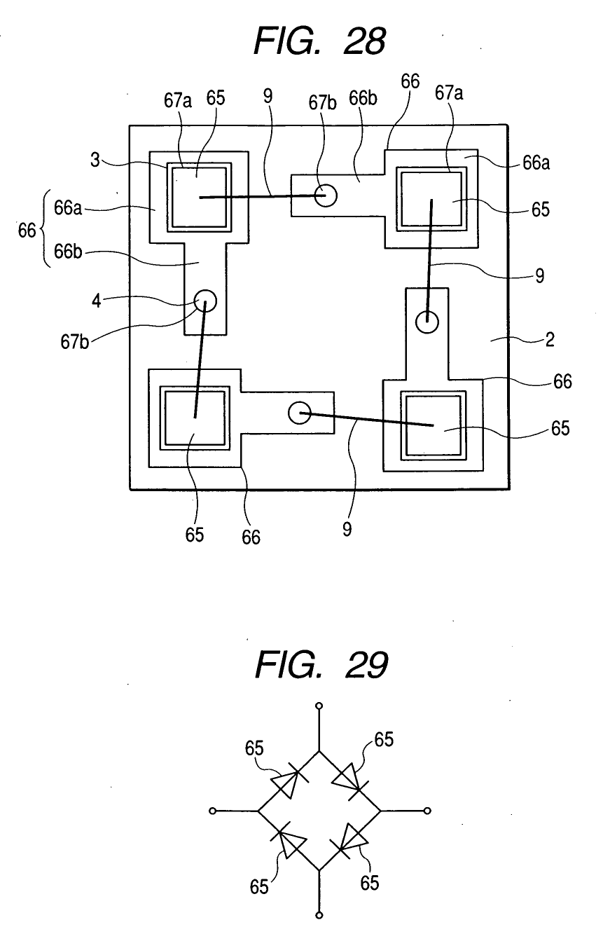

The DBM has a four-terminal structure wherein four Schottky diodes 65 are connected in a bridge form, as illustrated in an equivalent circuit schematic of FIG. 29. FIG. 27 is a schematic sectional view of the DBM, and FIG. 28 is a schematic see-through plan view, in which mounted members and others in the DBM are see-through.

As illustrated in FIG. 28, a supporting section 66 wherein a member-mounting section 3 and a wire-bonding section 4 are integrated with each other is arranged at each of four corners of a quadrilateral sealant 2. The supporting 66 is composed of a quadrilateral portion 66a and a slender portion 66b which projects slenderly from the center of one side of this quadrilateral portion 66a. The quadrilateral portion 66a is positioned at one of the corners of the quadrilateral sealant 2. The slender 66b extends in parallel to one side of the sealant 2. The slender portions 66b of the respective supporting sections 66 extend in the same direction along the circumference of the sealant.

A core metal layer 67a is formed on the quadrilateral portion 66a of each of the supporting sections 66. In the middle of the slender portion 66b, a core metal layer 67b is formed to overlap therewith. The quadrilateral portion 66a and the core metal layer 67a constitute each of the member-mounting sections 3, and the slender portion 66b and the core metal layer 67b constitute each of the wire-bonding sections 4. Each of the Schottky diodes 65 is fixed through an electroconductive adhesive, which is not illustrated, onto each of the member-mounting sections 3, and an electrode on the upper face of the Schottky diode 65 is connected to the wire-bonding section 4 adjacent to the member-mounting section 3 through a wire 9.

When a cross section of the DBM is viewed, a multi-layered wiring region 55a corresponding to the multi-layered wiring region 55 in the embodiment 3 illustrated in FIG. 20 is present on the rear face of the sealant 2. This multi-layered wiring region 55a has a first insulating film 57 and a second insulating film 59 which overlaps with this first insulating film 57 and contacts the sealant 2. Each of the supporting regions 66 is sandwiched between the first insulating film 57 and the second insulating film 59. On the quadrilateral portion 66a of the supporting region 66, one of the core metal layers 67a is formed and, and on the slender portion 66b thereof one of the core metal layers 67b is formed.

Each of the core metal layers 67a and the top end of each of the core metal layers 67b are projected to extend from the second insulating film 59 to the inside the sealant 2. Since each of the quadrilateral portions 66a and each of the core metal layers 67a constitute each of the member-mounting sections 3, each of the Schottky diode 65 is formed on the core metal layer 67a. Since each of the slender portions 66b and each of the core metal layers 67b constitute each of the wire-bonding sections 4, the core metal layer 67b is connected to the upper electrode of each of the Schottky diodes through each of the wires 9.

The lower face of the quadrilateral portion 66a of each of the supporting regions 66 penetrates the first insulating film 57 to be positioned on the same plane as the rear face of the first insulating film 57. This is based on the following: in the manufacture of the DBM, the first insulating film 57 is formed on the main face of a silicon wafer, which is not illustrated; holes (through holes) are made in the area of the first insulating film where the quadrilateral portion 66a is to be produced; the supporting region 66 (the quadrilateral portion 66a and the slender portion 66b) is then formed; and finally the silicon wafer is removed.

A mounting plating film 6a is formed on the rear face of each of the quadrilateral portions 66a exposed to the rear face of the first insulating film 57. Since the mounting plating film 6a is projected from the rear face of the first insulating film 57, the electrode comes to have a standoff structure.

Each of the Schottky diode 65 comes to have a structure having electrodes on the upper and lower faces thereof, and further the lower face electrode is fixed onto the corresponding core metal layers 67a through an electroconductive adhesive; therefore, the lower face electrode becomes electrically conductive to the corresponding mounting plating film 6a. In this way, the DBM (semiconductor device) 1F having the circuit structure illustrated in FIG. 29 is manufactured.

The semiconductor device (DBM) 1F in the present embodiment 4 is manufactured by use of a silicon wafer in the same way as in the above-mentioned embodiments, and is manufactured by forming a resin layer on the main face of the silicon wafer, removing the silicon wafer, and dividing the resin layer lengthwise and breadthwise.

According to the present embodiment 4, the DBM (semiconductor device) 1F which is thin, small-sized and inexpensive can be provided.

The present embodiment 4 also has some of the advantageous effects which the respective embodiments have.

### Embodiment 5

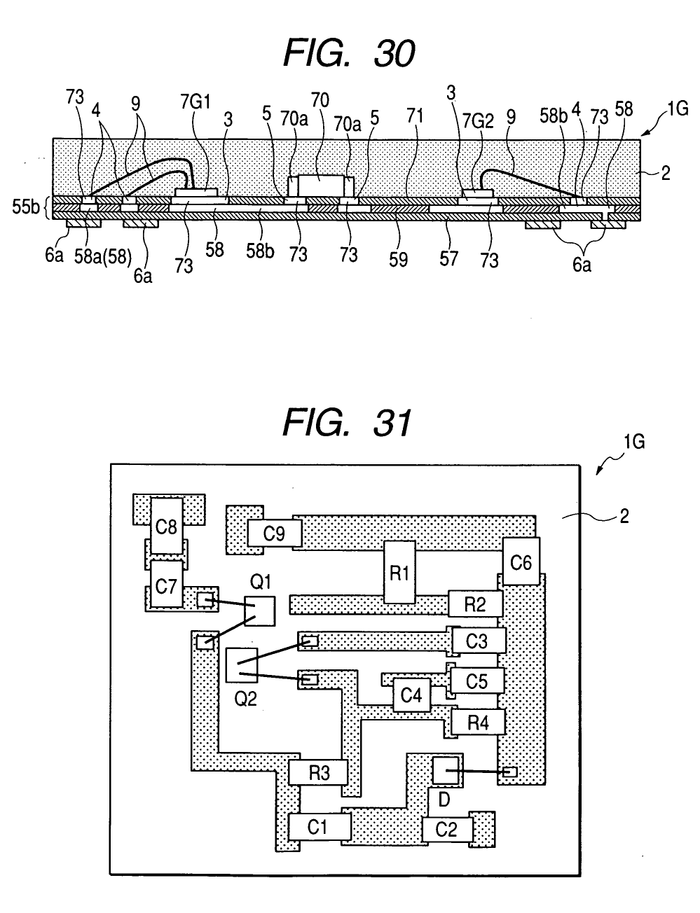

FIGS. 30 to 32 are views concerned with a different embodiment (embodiment 5) of the present invention. The present invention is an example wherein electrode-fixing sections, together with member-mounting sections and wire-bonding sections, are newly formed by the semiconductor device manufacturing method of the invention and the combination thereof makes it possible to manufacture not only individual semiconductor devices but also a thin one-packaged compound device having a circuit function or a module at will. The present embodiment 5 is a manufacture example of such a semiconductor device.

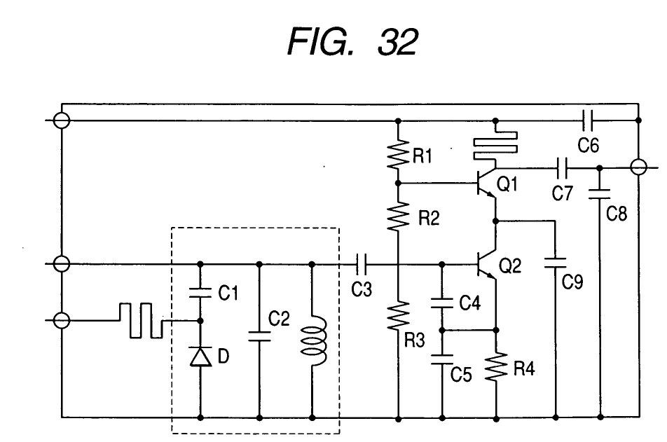

A semiconductor device 1G of the present embodiment 5 is a multi chip module (MCM) which constitutes an ordinary VCO (voltage controlled oscillator) having a Colpitts oscillating circuit. FIG. 31 is a schematic see-through plan view illustrating the layout of mounted members, and FIG. 32 is an equivalent circuit schematic thereof. In the plan view, some of the members, and others are omitted.

The VCO 1G has two transistor chips (Q1 and Q2), one diode chip (D), chip condensers (C1 to C9), chip resistors (R1 to R4), and others. The techniques of the embodiments 1 to 4 are used to form electrode-fixing sections 5 in addition to member-mounting sections 3 and wire-bonding sections 4 as illustrated in FIG. 30, and electrodes 70a of a chip member 70, which is a passive element such as a chip condenser or a chip resistor, are electrically connected to the electrode-fixing sections 5 by use of a jointing material which is not illustrated. Semiconductor chips 7G1 and 7G2 are mounted on the two member-mounting sections 3, and an electrode or electrodes of each of the semiconductor chips 7G1 and 7G2 are electrically connected to one of the wire-bonding sections 4 through a wire or wires 9.

In the semiconductor device (VCO) 1G of the present embodiment 5, a multi-layered wiring region 55b on the rear face of a sealant 2 has substantially the same structure as in the embodiment 4. However, in the present embodiment 5, its insulating film is made of a combination of a first insulating film 57 as the lowest layer, a second insulating film 59 as a middle layer, and a third insulating film 71 as an upper layer.

The wiring is composed of first wiring layers 58 and core metal layers 73 formed to overlap partially with the first wiring layers 58. The first wiring layers 58 are formed in through hole areas made in the first insulating film 57, and are formed thickly up to the height of the second insulating film 59. The first wiring layers 58 are made of independent regions 58a, which are formed in only the through hole areas, and extended regions 58b, which are extended onto the first insulating film 57.

The first wiring layers 58 and the core metal layers 73 thereon constitute the member-mounting sections 3, the wire-bonding sections 4 and the electrode-fixing sections 5. Mounting plating films 6a are formed on the surfaces of the first insulating layers 58, which are exposed to the rear face of the first insulating films 57. The mounting plating layers 6a are projected from the rear face of the first insulating film 57 to come to have a standoff structure.

The semiconductor device (VCO) 1G in the present embodiment 5 is manufactured by use of a silicon wafer in the same way as in the above-mentioned embodiments, and is manufactured by forming a resin layer on the main face of the silicon wafer, removing the silicon wafer, and dividing the resin layer lengthwise and breadthwise.

According to the present embodiment 5, the VCO (semiconductor device) 1G which is thin, small-sized and inexpensive can be provided.

The present embodiment 5 also has some of the advantageous effects which the respective embodiments have.

### Embodiment 6

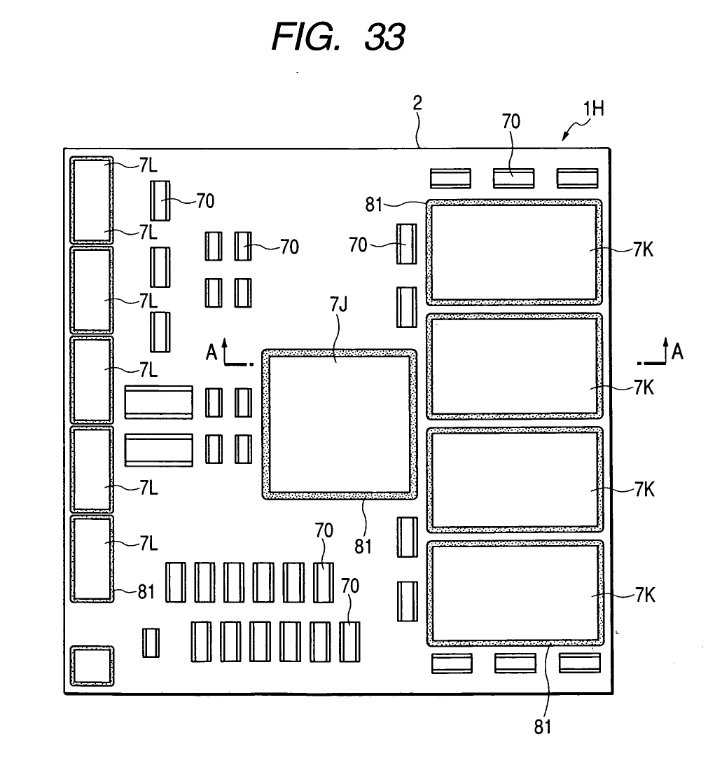

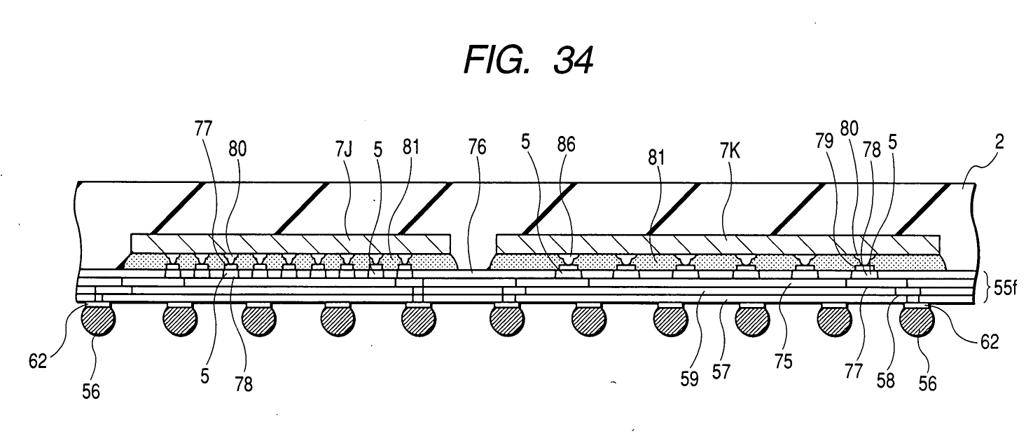

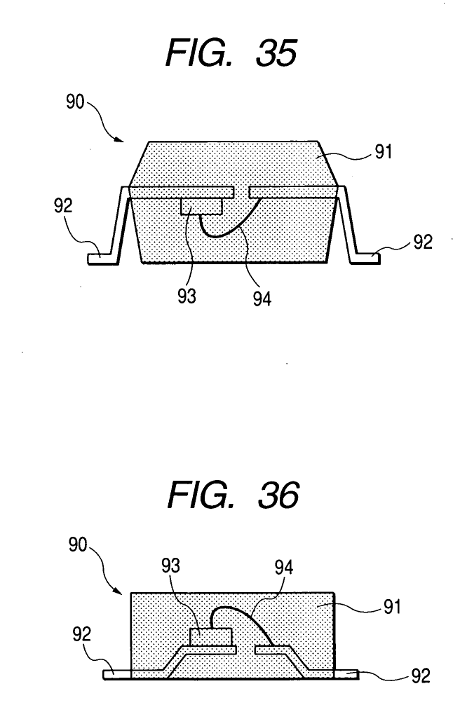

FIG. 33 is a schematic see-through plan view in which mounted members of a semiconductor device (MCM) which is a different embodiment (embodiment 6) of the present invention are see-through. FIG. 34 is a schematic sectional view of a portion of the MCM.

The semiconductor device 1H of the present embodiment 6 is an example wherein the present invention is applied to a ball grid array type semiconductor device having an MCM structure, and therein semiconductor device manufacturing techniques of the above-mentioned respective embodiments are used.

The semiconductor device 1H of the present embodiment 6 is a MCM module wherein LSIs such as a high-speed microprocessor (MP: super-small arithmetic processing device), main memories, and buffer memories are mounted.

In the semiconductor device 1H of the present embodiment 6, a multi-layered wiring region 55f on the rear face of a sealant 2 has substantially the same structure as in the embodiment 5, as illustrated in FIG. 34. However, in the case of the present embodiment 6, the number of insulating films and conductive layers which constitute interjacent wiring is larger.

FIG. 34 is a sectional view of a portion of the semiconductor device 1H. As illustrated in this figure, the topmost layer of the multi-layered wiring region 55f is a first insulating film 57. On this, the following are laminated toward the sealant 2: a second insulating film 59, a third insulating film 75, and a fourth insulating film 76. First wiring layers 58 are formed from through holes made in the first insulating film 57 to the first insulating film 57, and second wiring layers 77 are formed on the second insulating film 59. Core metal layers 78 are formed on the second wiring layers 77. Side faces of each of the core metal layers 78 are surround by the fourth insulating film 76, and the second wiring layer 77 areas where none of the core metal layers 78 are formed are covered with the fourth insulating film 76. A plating film 79 composed of a lower layer of Ni and an upper layer of Au is deposited on the main faces of the core metal layers.

In the present embodiment 6, semiconductor chips are mounted in a flip chip manner, and other members also have surface mount structures wherein their electrodes are connected. Thus, electrode-fixing sections 5, the sizes of which are suitably selected, are formed in areas including the core metal layers 78 and the plating films 79 and on the main face of the multi-layered wiring region 55f.

Since the electrodes of the semiconductor chips and the chip members are connected to the Au layers of the electrode-fixing sections, the reliability of the connection will be improved.

Plating films 62 are formed on the exposed faces of the first wiring layers 58 exposed to the rear face of the multi-layered region 55f. Ball electrodes 56 are fitted onto the plating films 62. The ball electrodes 56 are, for example, solder balls. In this way, the semiconductor device 1H turns into a BGA type.

As illustrated in the see-through plan view of FIG. 33, the semiconductor device 1H has a semiconductor chip 7J wherein an MPU is formed, plural semiconductor chips 7K wherein main memories (DRAM) are formed, plural semiconductor chips wherein buffer memories are formed, plural chip members 70 (passive elements which constitute condensers, resistor elements, and so on), and others.

Electrodes of the chip members 70 are mounted on electrode-fixing members for the chip members, which are not illustrated, by soldering in the same way as in the embodiment 5.

In the present embodiment 6, the semiconductor chips 7J, 7K and 7L are fixed in electrode-fixing sections 5 in a flip chip manner, as illustrated in FIG. 34. At this time, an anisotropic electroconductive resin 81 is interposed in the gap between the main face of the multi-layered wiring region 55f and the semiconductor chips 7J, 7K and 7L. In the anisotropic electroconductive resin 81, conductors present therein contact each other by compression based on gold bumps 80 and the electrode-fixing sections 5, so as to connecting the gold bumps 80 electrically to the electrode-fixing sections 5. The anisotropic electroconductive resin 81 is baked and cured in the state that they are electrically connected. Consequently, the semiconductor chips 7J, 7K and 7L are fixed onto the multi-layered region 55f.

In FIG. 34, a state that the semiconductor chips 7J and 7K are mounted in a flip chip manner is illustrated. The case of the semiconductor chip 7L is similar thereto.

In the manufacture of the semiconductor chip 1H of the present embodiment 6, a silicon wafer 15 having oxide films on the main face and the rear face thereof is used in the same way as in the respective embodiments. The multi-layered region 55f is formed on the main face of the silicon wafer 15, thereby forming the electrode-fixing sections 5 into a given pattern.

Next, the semiconductor chips 7J, 7K and 7L are mounted and the chip members 70 are mounted. Thereafter, a resin layer 20 covering the semiconductor chips 7J, 7K and 7L and the chip members 70 is formed on the main face side of the silicon wafer 15.

Next, the silicon wafer 15 and the oxide film are removed from the rear face of the resin layer 20, and subsequently the plating films 62 are formed on the first wiring layer 58 surfaces exposed to the rear face of the resin layer 20 and further ball electrodes 56 are fitted onto the plating films 62.

Next, the resin layer 20 is divided lengthwise and breadthwise to manufacture plural semiconductor devices 1H.

According to the present embodiment 6, the semiconductor chips 7J, 7K and 7L and the chip members 70 have surface mount structures. Thus, wire bonding, wherein the height of loops cannot be made low, is unnecessary. Therefore, the height of the resin layer 20, that is, the sealant 2 can be made low and further the semiconductor devices 1H can be made thin.

The present embodiment 6 also has some of the advantageous effects which the respective embodiments have.

The above has described the invention made of the present inventors specifically on the basis of its embodiments. Needless to say, however, the present invention is not limited to the above-mentioned embodiments, and can be modified into various embodiments within the scope which does not depart from the subject matters of the present invention.

The following briefly describes advantageous effects obtained by typical embodiments of the invention disclosed in the present application.

(1) Since facilities of the wafer process, wherein a semiconductor substrate is used, can be used, manufacture costs of a semiconductor device can be decreased.

(2) It is possible to provide a thin and small-sized semiconductor device.

(3) It is possible to provide, at a low cost, a thin and small-sized semiconductor device on which semiconductor elements, which are active members, and passive members are mounted. That is, it is possible to change metal pedestals in accordance with the use purpose thereof so as to be made into member-mounting sections, wire-bonding sections or electrode-fixing sections. As a result, various electronic members can be mounted, and a multi-chip module can be manufactured.

### INDUSTRIAL APPLICABILITY

As described above, the manufacturing method of a resin-sealed semiconductor device according to the present invention makes it possible to manufacture, at a low cost, a semiconductor device which has a surface mount structure and can be made thin, small and light. It is therefore possible to make small an electronic instrument into which the semiconductor device of the present invention is integrated, and reduce the manufacture costs thereof.

1. A semiconductor device, comprising:
a sealant comprised of an insulating resin;
plural metal layers formed inside the sealant, the rear faces thereof being exposed to the rear face of the sealant;
an electronic member which is fixed to the main face of one of the metal layers through the rear face thereof and has, over the main face thereof, one or more electrodes; and
one or more electroconductive wires for connecting the electrode to the main face of the other metal layers,
wherein the main face sides being positioned inside the sealant, of the metal layers become thick.

2. The semiconductor device according to claim 1, wherein projected portions which are one-stepwise projected by the same length are formed at plural positions to the rear face of the sealant, and the metal layers are formed in the projected portions, respectively.

3. The semiconductor device according to claim 1, wherein the rear faces of the metal layers and the rear face of the sealant are positioned over substantially the same plane.

4. The semiconductor device according to claim 1, wherein a metal plating film is formed to the rear faces of the metal layers.

5. The semiconductor device according to claim 4, wherein the metal plating layer comprises a lower layer of Ni and an upper layer of Au.

6. The semiconductor device according to claim 4, wherein ball electrodes are attached to the metal plating layer.

7. The semiconductor device according to claim 1, wherein the metal layers are positioned inside the circumferential edge of the sealant.

8. The semiconductor device according to claim 1, wherein the metal layers each comprise a metal-laminated film, a first metal film which is a strong member formed over this metal-laminated film, and a second metal film formed over the surface of this first metal film, and the second metal film is formed from the main face of the first metal film to a portion of circumferential faces thereof, so as to be thicker than the first metal film.

9. The semiconductor device according to claim 7, wherein the metal-laminated film has a lower layer of a Ti layer and an upper layer of a Ni layer, the first metal film is a Ni layer, and the second metal film has a lower layer of a Ni layer and an upper layer of a Au layer.

10. The semiconductor device according to claim 1, wherein the electronic member has electrodes over the upper and lower faces thereof, the electrode formed to the lower face is electrically connected to the one metal layer, and the electrode over the upper face is electrically connected to the other metal layer through the wire.

11. The semiconductor device according to claim 10, wherein the electronic member is a semiconductor chip in which a diode is formed.

12. The semiconductor device according to claim 1, wherein a semiconductor chip is fixed to the main face of the one metal layer through the rear face thereof, and an electrode of the main face of this semiconductor chip is connected to the other metal layers through electroconductive wire.

13. The semiconductor device according to claim 12, wherein a transistor is formed in the semiconductor chip.

14. The semiconductor device according to claim 12, wherein an IC is formed in the semiconductor chip.

15. The semiconductor device according to claim 1, wherein electrodes of an electronic member, the electrodes being positioned at both ends of the member, are mounted over the pair of the metal layers through an electroconductive jointing material.

16. The semiconductor device according to claim 1, wherein plural electrodes of one semiconductor chip are fixed to the metal layers in a flip chip manner.

17. The semiconductor device according to claim 1, wherein one or more semiconductor chips and one or more passive members are integrated into the sealant.

18. The semiconductor device according to claim 1, wherein a wiring region including one or more insulating layers and one or more electroconductive layers is formed to the rear face of the sealant, and the metal layers is formed of members comprising the plural electroconductive layers.

19. A manufacturing method of semiconductor devices, comprising the steps of:
preparing a semiconductor substrate;
forming oxide films over the main face and the rear face of the semiconductor substrate;
forming a metal-laminated film which constitutes metal layers over the oxide film;
forming a first metal film which constitutes the metal layers over the metal-laminated film;
forming a second metal film which constitutes the metal layers over the surface of the first metal layer;
fixing an electronic member having, over the main face thereof, one or more electrodes, to the main face of at least one metal layer out of the metal layers through the rear face thereof;
connecting the electrode of the electronic member to the other metal layers through an electroconductive wire or electroconductive wires;
forming, over the main face of the semiconductor substrate, a resin layer comprising an insulating resin for covering the electronic member and the wires;
removing the semiconductor substrate and the oxide film formed to the rear face of the semiconductor substrate so as to cause the oxide film over the main face of the semiconductor substrate to remain;
etching and removing the oxide film remaining to the rear face of the resin layer;
forming a metal plating layer over the surface of the metal layer exposed to the rear face of the resin layer; and
cutting the resin layer lengthwise and breadthwise to form the semiconductor devices.

20. The manufacturing method of the semiconductor devices according to claim 19,
wherein after the oxide films are formed over the main face and the rear face of the semiconductor substrate, plural hollows are made in the main face of the semiconductor substrate and further an oxide film is formed over the main face of the semiconductor substrate,
wherein, thereafter, the metal layers are formed, and
wherein, subsequently, the sealant is formed of an insulating resin so as to include the hollows also, thereby forming projected portions which are one-stepwise projected by the same length to the rear face of the sealant.

21. The manufacturing method of the semiconductor devices according to claim 19, further comprising the steps of:
forming an insulating film selectively over the main face of the semiconductor to make plural through holes;
forming an electroconductive layer to extend over the insulating film from the through holes;
forming an insulating film having through holes opposite to the electroconductive layer;
filling an electric conductor into the through holes; and
forming the metal-laminated film and the first metal film, or the metal-laminated film, the first and second metal films so as to overlap with the electric conductor, thereby forming the metal layers.

22. The manufacturing method of the semiconductor devices according to claim 19, further comprising the steps of:
forming an insulating film selectively over the main face of the semiconductor substrate to make plural through holes;
forming an electroconductive layer to the through hole portions and to extend over the insulating film from the through holes;
forming an insulating film having through holes opposite to the electroconductive layer; and
forming an electric conductor to overlap with the through hole portions, thereby forming the metal layers.

23. The manufacturing method of the semiconductor devices according to claim 22, wherein after the electroconductive layer is formed to the through hole portions and to extend over the insulating film from the through holes, the formation of an insulating film and the formation of an electroconductive layer are repeated one or more times, and finally the electric conductor is formed to overlap with the through hole portions, thereby forming the metal layers.

24. The manufacturing method of the semiconductor devices according to claim 19, wherein after the metal plating film is formed over the metal layers exposed to the rear face of the resin layer, ball electrodes are formed to the metal plating film.

25. The manufacturing method of the semiconductor devices according to claim 19, wherein as the semiconductor substrate, a silicon monocrystal substrate, a polysilicon substrate, or a sintered substrate made from silicon fine powder is used.

26. The manufacturing method of the semiconductor devices according to claim 19, wherein a semiconductor chip in which a diode is formed over the upper and lower faces is fixed, as the electronic member, to one out of the metal layers, thereby manufacturing a diode.

27. The manufacturing method of the semiconductor devices according to claim 19, wherein a semiconductor chip is fixed to the main face of the one metal layer through the rear face thereof, and an electrode of the main face of the semiconductor chip is connected to the other metal layers through wire.

28. The manufacturing method of the semiconductor devices according to claim 19, wherein electrodes of an electronic member, the electrodes being positioned at both sides of the member, are mounted over the pair of the metal layers through an electroconductive jointing material.

29. The manufacturing method of the semiconductor devices according to claim 19, wherein plural electrodes of one semiconductor chip are connected to the metal layers in a flip chip manner.

30. The manufacturing method of the semiconductor devices according to claim 19, wherein one or more semiconductor chips and one or more passive members are integrated into the sealant.
